(19) United States
(12) Patent Application Publication
(10) Pub. No.: US 2026/0068455 A1
(43) Pub. Date: Mar. 5, 2026

(54) DISPLAY DEVICE AND METHOD OF MANUFACTURING THE SAME

(71) Applicant: Samsung Display Co., Ltd., Yongin-si (KR)

(72) Inventors: KYEUK LEE, Yongin-si (KR); SUNKWANG KIM, Yongin-si (KR); SI HYUN AHN, Yongin-si (KR)

(73) Assignee: Samsung Display Co., Ltd., Yongin-si (KR)

(21) Appl. No.: 19/085,524

(22) Filed: Mar. 20, 2025

(30) Foreign Application Priority Data
Sep. 4, 2024 (KR) 10-2024-0119645

(51) Int. Cl. H10K 59/131; G09G 3/00; G09G 3/3233

(52) U.S. Cl. CPC H10K 59/131; G09G 3/006; G09G 3/3233; G09G 2300/0426; G09G 2300/0819; G09G 2300/0852; G09G 2300/0861; G09G 2330/12

(57) ABSTRACT

Provided are a display device and a method of manufacturing the same, wherein the display device includes a substrate which includes a display area including a subpixel and a peripheral area around the display area, horizontal power voltage lines which are disposed in the display area and extend in a first direction, vertical power voltage lines which are disposed in the display area, are positioned on a different layer from the horizontal power voltage lines, extend in a second direction, and are electrically connected to the horizontal power voltage lines, and test lines which are disposed in the peripheral area, are positioned in a different layer from the vertical power voltage lines, are positioned to be closer to the substrate than the vertical power voltage lines, extend in the second direction, and are electrically connected to the horizontal power voltage lines.

### CROSS-REFERENCES TO RELATED APPLICATION(S)

This application claims priority to and benefits of Korean Patent Application No. 10-2024-0119645 under 35 U.S.C. § 119, filed on Sep. 4, 2024, in the Korean Intellectual Property Office, the entire contents of which are incorporated herein by reference.

### BACKGROUND

### 1. Technical Field

Embodiments of the disclosure relate to a display device and a method of manufacturing the display device.

### 2. Description of the Related Art

In general, in display devices such as organic light-emitting display devices, transistors, connection electrodes, and interconnects are disposed in each subpixel to control the luminance and the like of each subpixel.

### SUMMARY

Embodiments of the disclosure may provide a display device in which defects in transistors, connection electrodes, and interconnects are tested, and a method of manufacturing the display device.

Additional aspects will be set forth in part in the description which follows and, in part, will be apparent from the description, or may be learned by practice of the presented embodiments of the disclosure.

An embodiment of the disclosure may provide a display device including a substrate which includes a display area including a subpixel and a peripheral area around the display area, horizontal power voltage lines which are disposed in the display area and extend in a first direction, vertical power voltage lines which are disposed in the display area, are positioned on a different layer from the horizontal power voltage lines, extend in a second direction intersecting the first direction, and are electrically connected to the horizontal power voltage lines, and test lines which are disposed in the peripheral area, are positioned in a different layer from the vertical power voltage lines, are positioned to be closer to the substrate than the vertical power voltage lines, extend in the second direction, and are electrically connected to the horizontal power voltage lines.

In the embodiment, the display device may further include a semiconductor layer positioned on an insulating layer that covers at least one of the horizontal power voltage lines.

In the embodiment, the semiconductor layer may include an oxide semiconductor material.

In the embodiment, the test lines may be positioned on an insulating layer that covers the semiconductor layer.

In the embodiment, the subpixel may include a transistor, and the test lines and gate electrodes of the transistor may be formed as a same layer.

In the embodiment, the test lines and at least one of the horizontal power voltage lines may be positioned on a same layer.

In the embodiment, the subpixel may include a capacitor, and the test lines and an electrode of the capacitor may be positioned on a same layer.

In the embodiment, the vertical power voltage lines may be positioned on an insulating layer that covers the test lines.

In the embodiment, the subpixel may include a transistor, and the test lines and source and drain electrodes of the transistor may be positioned on a same layer.

In the embodiment, the test lines may include a plurality of test lines electrically connected to correspond to each of a plurality of horizontal power voltage lines, and the plurality of test lines may be positioned on a same layer.

In the embodiment, the test lines may include a plurality of test lines electrically connected to correspond to each of a plurality of horizontal power voltage lines, and the plurality of test lines may be positioned on different layers.

In the embodiment, the test lines may be electrically connected to the horizontal power voltage lines through connection interconnects.

In the embodiment, the subpixel may include a transistor, the horizontal power voltage lines may include a horizontal first power line which is electrically connected to the transistor and extends in the first direction, the vertical power voltage lines may include a vertical first power line which traverses the subpixel in the second direction and is electrically connected to the horizontal first power line, and the test lines may include a first power test line electrically connected to the horizontal first power line.

In the embodiment, the horizontal power voltage lines may include a horizontal second power line which traverses the subpixel and extends in the first direction, the vertical power voltage lines may include a vertical second power line which traverses another subpixel of a pixel including the subpixel in the second direction and is electrically connected to the horizontal second power line, the horizontal second power line and the vertical second power line may be electrically connected to a display element, and the test lines may include a second power test line electrically connected to the second horizontal power line.

Another embodiment of the disclosure may provide a method of manufacturing a display device, the method including preparing a substrate which includes a display area including a subpixel and a peripheral area outside the display area, forming horizontal power voltage lines which are disposed in the display area and extend in a first direction, forming test lines which are disposed in the peripheral area, extend in a second direction intersecting the first direction, and are electrically connected to the horizontal power voltage lines, and forming vertical power voltage lines which are disposed in the display area, are positioned to be closer to the substrate than the vertical power voltage lines, extend in the second direction, and are electrically connected to the horizontal power voltage lines.

In the embodiment, the test lines and at least one of the horizontal power voltage lines may be formed on a same layer.

In the embodiment, the method may further include, after the forming of the horizontal power voltage lines, forming a semiconductor layer positioned on an insulating layer that covers at least one of the horizontal power voltage lines, wherein the test lines are positioned on an insulating layer that covers the semiconductor layer.

In the embodiment, the forming of the vertical power voltage lines may include forming an insulating layer that covers the test lines and forming the vertical power voltage lines to be positioned on the insulating layer.

Another embodiment of the present disclosure may provide an electronic device including a display device, wherein the display device includes: a substrate which includes a display area including a subpixel and a peripheral area outside the display area; horizontal power voltage lines which are disposed in the display area and extend in a first direction; vertical power voltage lines which are disposed in the display area, are positioned on a different layer from the horizontal power voltage lines, extend in a second direction intersecting the first direction, and are electrically connected to the horizontal power voltage lines; and test lines which are disposed in the peripheral area, are positioned in a different layer from the vertical power voltage lines, are positioned to be closer to the substrate than the vertical power voltage lines, extend in the second direction, and are electrically connected to the horizontal power voltage lines.

In the embodiment, the electronic device may be at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.

Other aspects, features and advantages of the disclosure will become better understood through the accompanying drawings, the claims, and the detailed description.

### BRIEF DESCRIPTION OF THE DRAWINGS

The above and other aspects, features, and advantages of certain embodiments will be more apparent from the following description taken in conjunction with the accompanying drawings, in which:

FIG. 1 is a schematic plan view illustrating a display device according to an embodiment of the disclosure;

FIG. 2 is an enlarged schematic view of portion A of FIG. 1;

FIG. 3 is a schematic diagram of an equivalent circuit of one subpixel included in the display device of FIG. 1;

FIG. 4 is a schematic layout illustrating positions of transistors, capacitors, and the like in pixels included in the display device of FIG. 1;

FIGS. 5 to 10 are schematic layouts illustrating, for each layer, components such as transistors and capacitors of the display device shown in FIG. 4;

FIG. 11 is a schematic cross-sectional view illustrating a cross section taken along line B-B′ of the display device shown in FIG. 4;

FIG. 12 is a schematic cross-sectional view illustrating a cross section taken along discontinuous line C-C′ of the display device shown in FIG. 2;

FIGS. 13 to 16 are schematic cross-sectional views illustrating a cross section taken along discontinuous line C-C′ of the display device shown in FIG. 2 according to another embodiment of the disclosure;

FIG. 17 is a schematic block diagram illustrating a display system according to an embodiment of the disclosure; and

FIG. 18 is a schematic view showing an example of a smart watch including a display device according to an embodiment of the disclosure.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” in case that preceding a list of elements, modify the entire list of elements and do not modify the individual elements of the list.

Since the disclosure can apply various transformations and have various embodiments, specific embodiments will be illustrated in the drawings and described in detail in the detailed description. The effects and features of the disclosure and methods of accomplishing the same will become apparent from the following description of the embodiments in detail, taken in conjunction with the accompanying drawings. The disclosure may, however, be embodied in many different forms and should not be construed as limited to the embodiments set forth herein.

In the following embodiments, the terms first, second, and the like do not have limited meaning but are used for the purpose of distinguishing one component from another component.

In the following embodiments, the expressions used in the singular such as “a,” “an,” and “the” are intended to include the plural forms as well, unless the context clearly indicates otherwise.

In the following embodiments, it will be understood that the terms such as “including,” “comprising,” and “having” specify the presence of stated features or components, but do not preclude the presence or addition of one or more other features or components.

In the following embodiments, in case that a unit, an area, a component, or the like is positioned on or above another part, the disclosure includes not only a case in which the unit, the area, the component, or the like is positioned directly above the other part, but also a case in which other units, other areas, other component, or the like may be positioned therebetween.

In the following embodiments, unless the terms “connecting” or “coupling” are clearly different in context, the terms “connecting” or “coupling” do not necessarily mean direct and/or fixed connection or coupling of two members, but do not exclude a member positioned between the two members.

In the drawings, components may be exaggerated or reduced in size for convenience of description. For example, the sizes and/or thicknesses of the respective components shown in the drawings are arbitrarily shown for convenience of description, and thus one or more embodiments are not necessarily limited thereto.

In the following examples, it will be understood that in case that a component, such as a layer, a film, a region, or a plate, is referred to as being “on” another component, the component may be directly on the other component or intervening components may be present thereon. In the drawings, components may be exaggerated or reduced in size for convenience of description. For example, the sizes and thicknesses of the respective components shown in the drawings are arbitrarily shown for convenience of description, and thus one or more embodiments are not necessarily limited thereto.

In the following embodiments, an X-axis, a Y-axis, and a Z-axis are not limited to three axes in a Cartesian coordinate system, but may be interpreted in a broad sense including the three axes. For example, the X-axis, Y-axis, and Z-axis may be orthogonal to each other, but may also refer to different directions that are not orthogonal to each other.

In the following embodiments, the term “line” may refer to an “interconnect.” This also applies to the embodiments and modifications thereof described below.

In the following embodiments, the term “horizontal” refers to a target straight line extending in a first direction in the same manner as a reference straight line extending in the first direction (or x-axis direction). The term “vertical” refers to a target straight line extending in a second direction (or y-axis direction) that intersects the reference straight line extending in the first direction (or x-axis direction).

Hereinafter, an example embodiments of the disclosure will be described in detail with reference to the accompanying drawings, wherein like reference numerals refer to the same or corresponding components throughout the drawings, and a redundant description thereof will be omitted.

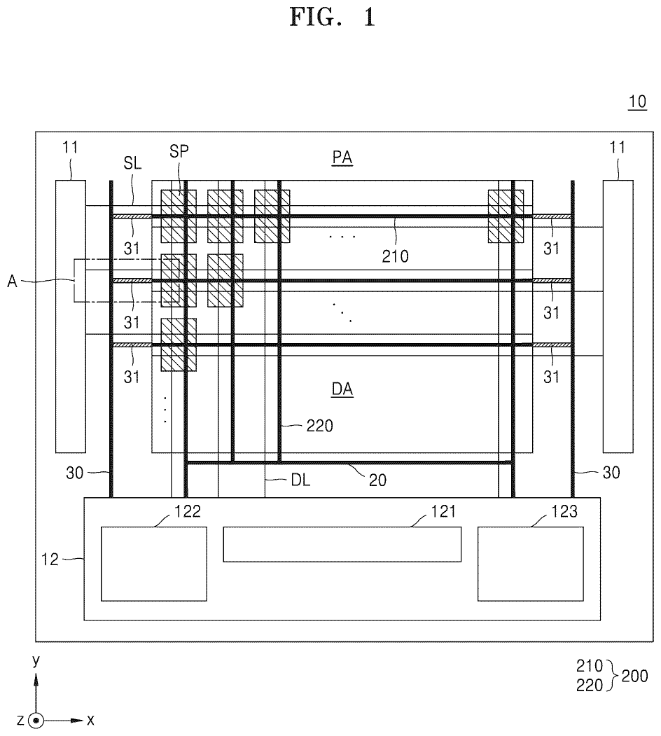

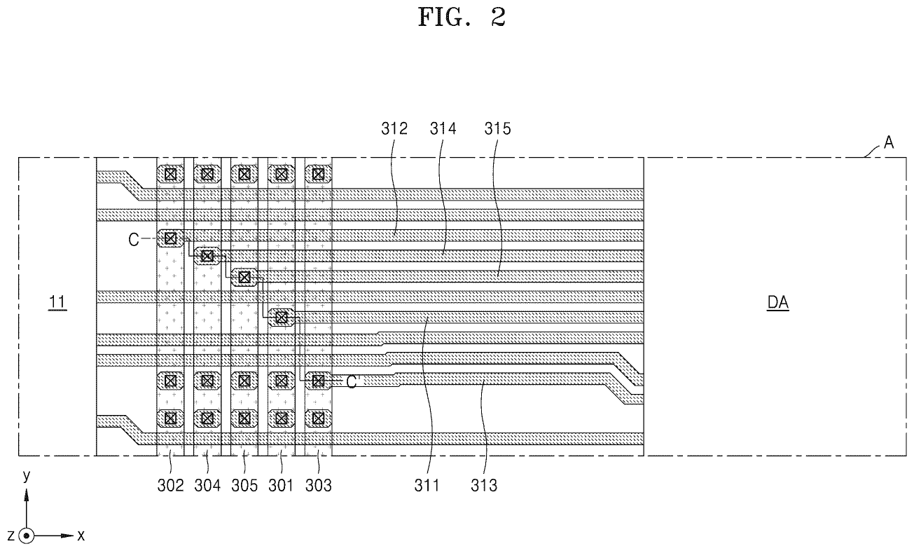

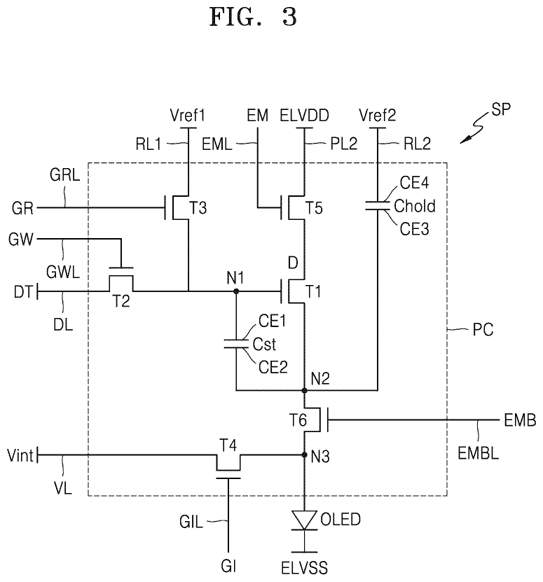

FIG. 1 is a schematic plan view illustrating a display device 10 according to an embodiment of the disclosure. FIG. 2 is an enlarged schematic view of portion A of FIG. 1. FIG. 3 is a schematic diagram of an equivalent circuit of one subpixel SP included in the display device 10 of FIG. 1.

Referring to FIGS. 1 to 3, the display device 10 according to the embodiment may be one of various products such as a smartphone, a tablet personal computer, a laptop computer, a television, or a billboard.

The display device 10 may include a display area DA and a peripheral area PA outside the display area DA. The display area DA may be a portion in which an image is displayed, and multiple pixels may be disposed in the display area DA. When viewed in a direction perpendicular to a plane parallel to the display device 10, the display area DA may have various shapes such as a circular shape, an oval shape, a polygonal shape, and a shape of a specific figure.

The peripheral area PA may be disposed outside the display area DA. Various types of driving circuits may be positioned in the peripheral area PA. For example, scan driving circuits 11 that generate a scan signal and an emission control signal may be positioned in the peripheral area PA at both sides of the display area DA in the first direction (or x-axis direction). According to an optional embodiment, the scan driving circuit 11 that generates a scan signal and an emission control driving circuit that generates an emission control signal may be provided separately. For example, the scan driving circuit 11 and the emission control driving circuit may be positioned in the peripheral area PA at both sides of the display area DA in first direction (or x-axis direction), respectively.

An integrated circuit 12 for driving the display device 10 may be disposed in the peripheral area PA of the display device 10. Such an integrated circuit 12 may include a data driving circuit 121 that generates a data signal and also may further include a controller 122 that generates a control signal for controlling the scan driving circuit 11, the emission control driving circuit, and the data driving circuit 121. The integrated circuit 12 may further include a power supply 123 that converts input voltages (for example, a battery voltage and a system voltage) into power voltages. For example, the power voltage may include an initialization voltage Vint, a first reference voltage Vref1, a second reference voltage Vref2, a first power voltage ELVDD, and a second power voltage ELVSS. For example, the integrated circuit 12 may be positioned in the peripheral area PA at a lower end portion of the display area DA in the second direction (or y-axis direction).

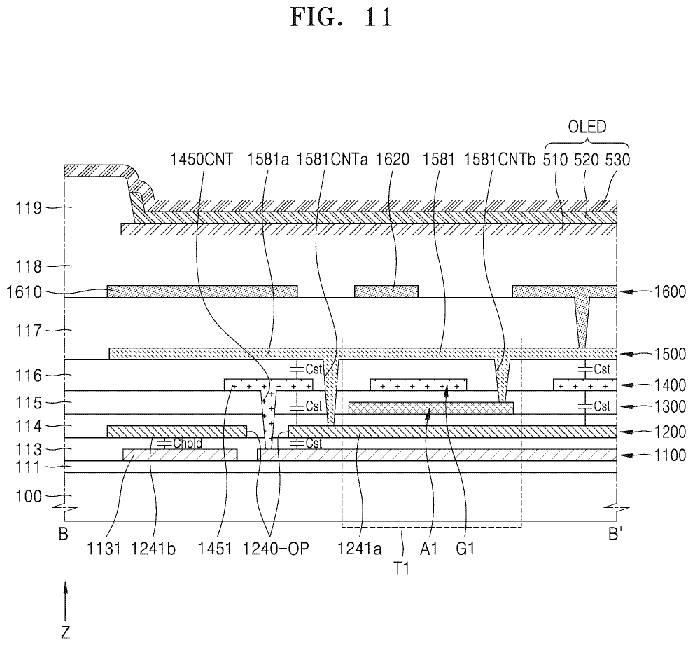

Since the display device 10 includes a substrate 100 (see FIG. 11), it may be considered that the substrate 100 may have the display area DA and the peripheral area PA as described above. Hereinafter, for convenience, it will be described that the substrate 100 may have the display area DA and the peripheral area PA. Various components included in the display device 10 may be positioned on the substrate 100. The substrate 100 may include glass, a metal, or a polymer resin.

Hereinafter, an example in which the display device 10 according to an embodiment of the disclosure is an organic light-emitting display device will be described. However, the display device 10 of the disclosure is not limited thereto. As another embodiment, the display device 10 of the disclosure may be a display device such as an inorganic light-emitting display device, an inorganic electroluminescence (EL) display device, or a quantum dot light-emitting display device. For example, an emission layer of a display element included in a display device may include an organic material or an inorganic material. The display device may have the emission layer and a quantum dot layer positioned on a path of light emitted from the emission layer.

Multiple pixels may be positioned in the display area DA. Each of the pixels may include multiple subpixels SP, and each of the subpixels SP may include a display element such as an organic light-emitting diode OLED. The subpixel SP may emit, for example, red, green, blue or white light.

The subpixel SP may be electrically connected to peripheral circuits disposed in the peripheral area PA. The scan driving circuit 11, the integrated circuit 12, and the like may be disposed in the peripheral area PA.

The scan driving circuit 11 may provide a scan signal to the pixel through scan lines SL such as a write signal line GWL, a reference voltage signal line GRL, an initialization signal line GIL, a first emission control line EML, and a second emission control line EMBL. The scan lines SL may extend in the first direction (or x-axis direction) in the display area DA to be commonly connected to multiple subpixels SP disposed in each row.

The integrated circuit 12 may include the data driving circuit 121, the controller 122, and the power supply 123 and may be in the form of a driving chip to transmit various signals or power to the driving circuits or the pixels. A data signal generated in the data driving circuit 121 may be transmitted to the pixels through data lines DL, and a control signal generated in the controller 122 may be transmitted to each of the driving circuits. In addition, power and voltage from the power supply 123 may be transmitted to power voltage lines 200 of the display area DA through each of power voltage supply interconnects 20. The power voltage supply interconnects 20 may be disposed in the peripheral area PA and electrically connect the power voltage lines 200 of the display area DA to the power supply 123.

According to an embodiment of the disclosure, the power voltage lines 200 of the display area DA may be formed in a mesh form. The power voltage lines 200 may include horizontal power voltage lines 210 (first direction power voltage lines) extending in the first direction (or x-axis direction) and vertical power voltage lines 220 (second direction power voltage lines) extending in the second direction (or y-axis direction) intersecting the first direction (or x-axis direction).

Referring to FIGS. 1 and 3 together, the power voltage lines 200 may include first power lines PL2 to which the first power voltage ELVDD is suppled, second power lines to which the second power voltage ELVSS is supplied, initialization voltage lines VL to which the initialization voltage Vint is suppled, and reference voltage lines to which the first and second reference voltages Vref1 and Vref2 are respectively supplied. The specific details of each power voltage line 200 will be described below with reference to a circuit diagram of a pixel circuit of FIG. 3.

Although not shown in FIG. 1, the power voltage supply interconnects 20 may include first power supply interconnects, second power supply interconnects, initialization voltage supply interconnects, and reference voltage supply interconnects. The power supply 123 may provide the first power voltage ELVDD (driving voltage) to the first power line PL2 through the first power supply interconnect and the second power voltage ELVSS (common voltage) to the second power line through the second power supply interconnect. The power supply 123 may provide the initialization voltage Vint to the initialization voltage line VL through the initialization voltage supply interconnect and may provide the first and second reference voltages Vref1 and Vref2 to the reference voltage lines through the reference voltage supply interconnects.

The first power supply interconnect may transmit the first power voltage ELVDD to the subpixel SP through the first power line PL2. The first power supply interconnect may be disposed in the peripheral area PA between the integrated circuit 12 and the display area DA. The first power supply interconnect may be electrically connected to the first power lines PL2 disposed in a mesh form in the display area DA. The first power lines PL2 may include horizontal first power lines extending in the first direction (or x-axis direction) and vertical first power lines extending in the second direction (or y-axis direction). The horizontal first power lines and the vertical first power lines may be positioned on different layers. For example, a layer on which the horizontal first power lines are positioned may be a layer closer to the substrate 100 than a layer on which the vertical first power lines are positioned. For example, the horizontal first power lines may be formed first, and then the vertical first power lines may be formed. The horizontal first power lines and the vertical first power lines may be electrically connected to each other through contact holes at least portions at which the horizontal first power lines and the vertical first power lines are intersect each other. The first power lines PL2 may be electrically connected to the subpixels SP. The first power lines PL2 may be electrically connected to at least a transistor included in the subpixel SP. Accordingly, the subpixel SP may be electrically connected to the first power supply interconnect to receive the first power voltage ELVDD, which is a driving voltage, from the power supply 123. Meanwhile, through the first power lines PL2 with a mesh form, the first power lines PL2 may have a uniform potential in various portions inside the first power lines PL2.

The second power supply interconnect supplies the second power voltage ELVSS to a counter electrode 530 (see FIG. 11) of the organic light-emitting diode OLED. The second power supply interconnect may be disposed in the peripheral area PA between the integrated circuit 12 and the display area DA. However, one or more embodiments are not limited thereto, and the second power supply interconnect may be disposed in the peripheral area PA and may have a loop shape of which one side is open. The second power supply interconnect may be electrically connected to the second power lines arranged in a mesh form in the display area DA. The second power lines may include horizontal second power lines extending in the first direction (or x-axis direction) and vertical second power lines extending in the second direction (or y-axis direction). The horizontal second power lines and the vertical second power lines may be positioned on different layers. For example, a layer on which the horizontal second power lines are positioned may be a layer closer to the substrate 100 than a layer on which the vertical second power lines are positioned. For example, the horizontal second power lines may be formed first, and then the vertical second power lines may be formed. The horizontal second power lines and the vertical second power lines may be electrically connected through contact holes at least portions at which the horizontal second power lines and the vertical second power lines intersect each other. The organic light-emitting diode OLED may be electrically connected to the second power lines. For example, the counter electrode 530 (see FIG. 11) of the organic light-emitting diode OLED may be electrically connected to the second power lines outside the display area DA. Accordingly, the counter electrode 530 may receive the second power voltage ELVSS from the power supply 123. Through the second power lines with a mesh form, it is possible to prevent or minimize a deviation from occurring in the second power voltage ELVSS applied to the counter electrode 530 in the display area DA.

The initialization voltage lines VL may transmit the initialization voltage Vint, which is transmitted from the power supply 123 through the initialization voltage supply lines, to each of the subpixels SP. The initialization voltage lines VL may be also disposed in a mesh form in the display area DA. The initialization voltage lines VL may include horizontal initialization voltage lines extending in the first direction (or x-axis direction) and vertical initialization voltage lines extending in the second direction (or y-axis direction). The horizontal initialization voltage lines and the vertical initialization voltage lines may be positioned on different layers. For example, a layer on which the horizontal initialization voltage lines are positioned may be a layer closer to the substrate 100 than a layer on which the vertical initialization voltage lines are positioned. For example, the horizontal initialization voltage lines may be formed first, and then the vertical initialization voltage lines may be formed. The horizontal initialization voltage lines and the vertical initialization voltage lines may be electrically connected through contact holes at least portions at which the horizontal initialization voltage lines and the vertical initialization voltage lines intersect each other. The horizontal initialization voltage lines may be electrically connected to an initialization transistor T4 (see FIG. 3). Therefore, in case that the initialization transistor T4 is turned on, the initialization voltage Vint may be supplied to initialize the organic light-emitting diode OLED.

The reference voltage lines may transmit the first and second reference voltages Vref1 and Vref2, which are transmitted from the power supply 123 through the reference voltage supply lines, to each subpixel SP. The reference voltage lines may be also disposed in a mesh form in the display area DA. The reference voltage lines may include horizontal reference voltage lines extending in the first direction (or x-axis direction) and vertical reference voltage lines extending in the second direction (or y-axis direction). Meanwhile, the reference voltage lines may include first reference voltage lines RL1 and second reference voltage lines RL2, and the first reference voltage line RL1 and the second reference voltage line RL2 may transmit the first reference voltage Vref1 and the second reference voltage Vref2 to each subpixel SP.

The first reference voltage lines RL1 may include horizontal first reference voltage lines extending in the first direction (or x-axis direction) and vertical first reference voltage lines extending in the second direction (or y-axis direction). The horizontal first reference voltage lines and the vertical first reference voltage lines may be positioned on different layers. For example, a layer on which the horizontal first reference voltage lines are positioned may be a layer closer to the substrate 100 than a layer on which the vertical first reference voltage lines are positioned. For example, the horizontal first reference voltage lines may be formed first, and then the vertical first reference voltage lines may be formed. The horizontal first reference voltage lines and the vertical first reference voltage lines may be electrically connected at least portions at which the horizontal first reference voltage lines and the vertical first reference voltage lines intersect each other. The horizontal first reference voltage lines may be electrically connected to a reference voltage transistor T3 (see FIG. 3). Therefore, in case that the reference voltage transistor T3 is turned on, the first reference voltage Vref1 may be supplied to compensate for a threshold voltage of a driving transistor T1 (see FIG. 3).

The second reference voltage lines RL2 may include horizontal second reference voltage lines arranged to extend in the first direction (or x-axis direction) and vertical second reference voltage lines arranged to extend in the second direction (or y-axis direction). The horizontal second reference voltage lines and the vertical second reference voltage lines may be positioned on different layers. For example, a layer on which the horizontal second reference voltage lines are positioned may be a layer closer to the substrate 100 than a layer on which the vertical second reference voltage lines are positioned. For example, the horizontal second reference voltage lines may be formed first, and then the vertical second reference voltage lines may be formed. Meanwhile, the horizontal second reference voltage lines may be positioned on a layer closer to the substrate 100 than a layer on which the remaining horizontal power voltage lines 210 described above are positioned. For example, after the horizontal second reference voltage lines are formed first, the remaining horizontal power voltage lines 210 may be formed, and then the vertical power voltage lines 220 may be formed.

The horizontal second reference voltage lines and the vertical second reference voltage lines may be electrically connected through contact holes at least portions at which the horizontal second reference voltage lines and the vertical second reference voltage lines intersect each other. The horizontal second reference voltage lines may be electrically connected to a capacitor. Therefore, the capacitor may accumulate electric charges based on the second reference voltage Vref2.

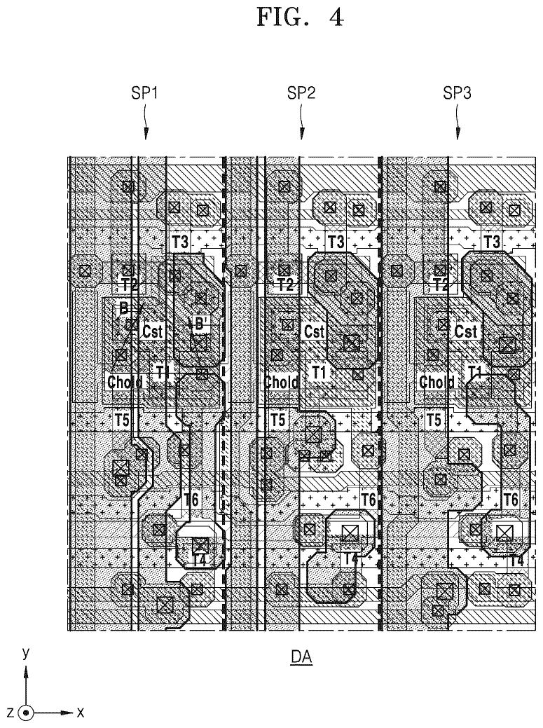

A positional relationship between respective interconnects will be described in more detail with reference to the circuit diagram of the pixel circuit of FIG. 3, plan views for each layer of a pixel circuit of FIGS. 4 to 10, and a cross-sectional view of a pixel circuit of FIG. 11.

Meanwhile, the data driving circuit 121 may generate a data signal DT (see FIG. 3), and the generated data signal DT may be transmitted to the subpixel SP through a data line DL. The data line DL may extend in the second direction (or y-axis direction) in the display area DA and may be commonly connected to multiple subpixels SP disposed in each column.

According to an embodiment of the disclosure, test lines 30 may be positioned in the peripheral area PA. The test lines 30 may be positioned in at least one peripheral area PA at both sides of the display area DA in the first direction (or x-axis direction). The test lines 30 may be positioned in the corresponding peripheral area PA between the scan driving circuit 11 and the display area DA. The test lines 30 may be positioned in the corresponding peripheral area PA between the emission control driving circuit and the display area DA. The test lines 30 may have a shape that extends substantially in the second direction (or y-axis direction).

Referring again to FIGS. 1 to 3, the test lines 30 may be electrically connected to the power voltage lines 200 disposed in the display area DA. The test lines 30 may include multiple lines and thus may be electrically connected to each of the power voltage lines 200. The test lines 30 may include a first power test line 301 electrically connected to the first power lines PL2 (see FIG. 3) to which the first power voltage ELVDD is supplied, a second power test line 302 electrically connected to second power lines to which the second power voltage ELVSS is supplied, an initialization voltage test line 303 connected to the initialization voltage lines VL (see FIG. 3) to which the initialization voltage Vint is supplied, a first reference voltage test line 304 connected to the first reference voltage lines RL1 (see FIG. 3) to which the first reference voltage Vref1 is supplied, and a second reference voltage test line 305 connected to the second reference voltage lines RL2 (see FIG. 3) to which the second reference voltage Vref2 is supplied.

The test lines 30 may be electrically connected to the power voltage lines 200 through connection interconnects 31. The connection interconnects 31 are disposed in the peripheral area PA. The connection interconnects 31 are disposed between the test lines 30 and the display area DA and may extend in the first direction (or x-axis direction). The connection interconnects 31 may include multiple interconnects to electrically connect each of the power voltage lines 200 to the test lines 30. The connection interconnects 31 may include a first connection interconnect 311 for electrically connecting the first power lines PL2, to which the first power voltage ELVDD is supplied, to the first power test line 301, a second connection interconnect 312 for electrically connecting the second power lines, to which the second power voltage ELVSS is supplied, to the second power test line 302, a third connection interconnect 313 for electrically connecting the initialization voltage lines VL, to which the initialization voltage Vint is supplied, to the initialization voltage test line 303, a fourth connection interconnect 314 for electrically connecting the first reference voltage lines RL1, to which the first reference voltage Vref1 is supplied, to the first reference voltage test line 304, and a fifth connection interconnect 315 for electrically connecting the second reference voltage lines RL2, to which the second reference voltage Vref2 is supplied, to the second reference voltage test line 305.

The connection interconnects 31 may be positioned on a different layer from the test lines 30 and/or the power voltage lines 200. For example, the connection interconnects 31 may be electrically connected to the test lines 30 and the power voltage lines 200 through contact holes at both end portions of the connection interconnects 31. However, the disclosure is not limited thereto, and the connection interconnects 31 may be positioned on the same layer as the test lines 30. For example, the connection interconnects 31 may be formed integrally with the test lines 30.

The test lines 30 may be positioned on a different layer from at least one of the power voltage lines 200. As described above, the power voltage lines 200 may include the horizontal power voltage lines 210 and the vertical power voltage lines 220. The horizontal power voltage lines 210 and the vertical power voltage lines 220 may be positioned on different layers and may be electrically connected to each other through contact holes. For example, the test lines 30 may be positioned at a different layer from the vertical power voltage lines 220. The test lines 30 may be positioned on a layer closer to the substrate 100 than a layer on which the vertical power voltage lines 220 are positioned. For example, the test lines 30 may be formed before the vertical power voltage lines 220 are formed.

The test lines 30 may be electrically connected to the power supply 123 to receive power or voltage required for a test. However, the disclosure is not limited thereto, and the test lines 30 may be electrically connected to the power supply 123 for a test to receive power or voltage required for a test. In another embodiment, end portions of the test lines 30 may be exposed in the form of terminals to receive power or voltage required for a test from the external power supply 123.

According to an embodiment of the disclosure, in order to implement high-resolution pixels, the power voltage lines 200 are implemented in a mesh form in the display area DA. The horizontal power voltage lines 210 and the vertical power voltage lines 220 may be positioned on different layers, and in particular, the vertical power voltage lines 220 are formed after the horizontal power voltage lines 210 are formed. For example, before the vertical power voltage lines 220 are formed, it is impossible to test a fine contact area (FCA) to test defects in transistors in a pixel circuit. This is because it is difficult to drive the entire display area DA before the vertical power voltage lines 220 are formed. According to an embodiment of the disclosure, the entire display area DA may be driven by the test lines 30 even before the vertical power voltage lines 220 are formed. The test lines 30 are formed before the vertical power voltage lines 220 and may be electrically connected to the horizontal power voltage lines 210. The test lines 30 extend in a direction intersecting the horizontal power voltage lines 210 and are formed in the peripheral area PA. Therefore, the test lines 30 and the horizontal power voltage lines 210 are implemented in a global mesh form. Accordingly, the entire display area DA may be driven even before the vertical power voltage lines 220 are formed, and thus there may be an effect of enabling an FCA test to be performed. In addition, since defects may be repaired before the vertical power voltage lines 220 are formed, there is an effect of making repair easy.

Hereinafter, the subpixel SP of FIG. 1 will be described in detail with reference to FIG. 3. As shown in FIG. 3, the subpixel SP may include a pixel circuit PC and the organic light-emitting diode OLED electrically connected thereto.

The pixel circuit PC may include multiple transistors T1 to T6, a storage capacitor Cst, and a hold capacitor Chold. Multiple transistors T1 to T6, the storage capacitor Cst, and the hold capacitor Chold may be electrically connected to signal lines GWL, GRL, GIL, EML, DL, and EMBL, the initialization voltage line VL, the first and second reference voltage lines RL1 and RL2, and the first power line PL2.

Multiple transistors T1 to T6 may include the driving transistor T1, a switching transistor T2, the reference voltage transistor T3, the initialization transistor T4, a first emission control transistor T5, and a second emission control transistor T6.

The organic light-emitting diode OLED may include a pixel electrode 510 (anode) and the counter electrode 530 (cathode). The pixel electrode 510 (see FIG. 11) of the organic light-emitting diode OLED may be electrically connected to the driving transistor T1 through the second emission control transistor T6 to receive a driving current, and the counter electrode 530 (see FIG. 11) may receive the second power voltage ELVSS. The organic light-emitting diode OLED may generate light with luminance corresponding to a driving current.

Multiple transistors T1 to T6 may be n-channel metal oxide semiconductors (NMOSs) (n-channel metal oxide silicon field effect transistors (MOSFETs)). Each of multiple transistors T1 to T6 may include an oxide semiconductor layer. For example, the oxide semiconductor layer may include an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). For example, the oxide semiconductor layer may include InSnZnO (ITZO), InGaZnO (IGZO), or the like.

The signal lines may include the write signal line GWL that transmits a write signal GW (scan signal), the reference voltage signal line GRL that transmits a reference voltage signal GR, the initialization signal line GIL that transmits an initialization signal GI, the first emission control line EML that transmits a first emission control signal EM, the second emission control line EMBL that transmits a second emission control signal EMB, and the data line DL that intersects the write signal line GWL and transmits the data signal DT.

The power voltage lines 200 may include the initialization voltage line VL, the first reference voltage line RL1, the second reference voltage line RL2, the first power line PL2, and the second power line electrically connected to the counter electrode 530 (see FIG. 11) of the organic light-emitting diode OLED. The initialization voltage line VL may transmit the initialization voltage Vint for initializing the pixel electrode of the organic light-emitting diode OLED, the first reference voltage line RL1 may transmit the first reference voltage Vref1 to a driving gate electrode G1 of the driving transistor T1, the second reference voltage line RL2 may transmit the second reference voltage Vref2 to one end of the hold capacitor Chold, and the first power line PL2 may transmit the first power voltage ELVDD, which is a driving voltage, to the driving transistor T1.

The driving gate electrode G1 of the driving transistor T1 may be electrically connected to the storage capacitor Cst through a first node N1. A drain region of the driving transistor T1 may be electrically connected to the first power line PL2 through the first emission control transistor T5. A source region of the driving transistor T1 may be electrically connected to the pixel electrode of the organic light-emitting diode OLED through the second emission control transistor T6. The driving transistor T1 may receive the data signal DT according to the switching operation of the switching transistor T2 and may supply a driving current to the organic light-emitting diode OLED. For example, the driving transistor T1 may control an amount of a current flowing to the organic light-emitting diode OLED in response to a voltage which is applied to the first node N1 and changed according to the data signal DT.

A switching gate electrode G2 of the switching transistor T2 may be electrically connected to the write signal line GWL that transmits the write signal GW, any one of a source region and a drain region of the switching transistor T2 may be electrically connected to the data line DL, and the other of the source region and the drain region of the switching transistor T2 may be electrically connected to the driving gate electrode G1 of the driving transistor T1 through the first node N1. The switching transistor T2 may transmit the data signal DT from the data line DL to the first node N1 in response to a voltage applied to the write signal line GWL. For example, the switching transistor T2 may be turned on according to the write signal GW received through the write signal line GWL to perform a switching operation of transmitting the data signal DT transmitted through the data line DL to the driving transistor T1 through the first node N1.

A reference voltage gate electrode G3 of the reference voltage transistor T3 may be electrically connected to the reference voltage signal line GRL that transmits the reference voltage signal GR, any one of a source region and a drain region of the reference voltage transistor T3 may be electrically connected to the first reference voltage line RL1, and the other of the source region and the drain region of the reference voltage transistor T3 may be electrically connected to the driving gate electrode G1 of the driving transistor T1 through the first node N1. The reference voltage transistor T3 may transmit the first reference voltage Vref1 from the first reference voltage line RL1 to the first node N1 in response to a voltage applied to the reference voltage signal line GRL. If necessary, the reference voltage signal line GRL may be the write signal line GWL in a subpixel which belongs to a previous row and is adjacent to the subpixel SP and electrically connected to the same data line DL. For example, the reference voltage signal GR may be referred to as a previous write signal GW (previous scan signal).

An initialization gate electrode G4 of the initialization transistor T4 may be electrically connected to the initialization signal line GIL, any one of a source region and a drain region of the initialization transistor T4 may be electrically connected to the pixel electrode of the organic light-emitting diode OLED through a third node N3, and the other of the source region and the drain region of the initialization transistor T4 may be electrically connected to the initialization voltage line VL to receive the initialization voltage Vint. The initialization transistor T4 may be turned on according to the initialization signal GI received through the initialization signal line GIL to initialize the pixel electrode of the organic light-emitting diode OLED. If necessary, the initialization signal line GIL may be the write signal line GWL in a subpixel which belongs to a next row and is adjacent to the subpixel SP and electrically connected to the same data line DL. For example, the initialization signal GI may be referred to as a next write signal GW (next scan signal).

A first emission control gate electrode G5 of the first emission control transistor T5 may be electrically connected to the first emission control line EML, any one of a source region and a drain region of the first emission control transistor T5 may be electrically connected to the first power line PL2, and the other thereof may be electrically connected to the drain region of the driving transistor T1. The first emission control transistor T5 is turned on according to the first emission control signal EM received through the first emission control line EML so that the first power voltage ELVDD (driving voltage) is transmitted to the organic light-emitting diode OLED to allow a driving current to flow to the organic light-emitting diode OLED.

A second emission control gate electrode G6 of the second emission control transistor T6 may be electrically connected to the second emission control line EMBL, any one of a source region and a drain region of the second emission control transistor T6 may be electrically connected to the pixel electrode of the organic light-emitting diode OLED, and the other thereof may be electrically connected to the source region of the driving transistor T1. The second emission control transistor T6 may be turned on according to the second emission control signal EMB received through the second emission control line EMBL to connect the source region of the driving transistor T1 to the pixel electrode of the organic light-emitting diode OLED. Although the first emission control transistor T5 and the second emission control transistor T6 are illustrated in FIG. 2 as operating in response to different control signals EM and EMB, the disclosure is not limited thereto, and the first emission control transistor T5 and the second emission control transistor T6 may operate in response to the same control signal.

The storage capacitor Cst may include a first capacitor electrode CE1 and a second capacitor electrode CE2. The first capacitor electrode CE1 of the storage capacitor Cst may be electrically connected to the driving gate electrode G1 of the driving transistor T1 through the first node N1, and the second capacitor electrode CE2 of the storage capacitor Cst may be electrically connected to the source region of the driving transistor T1 through a second node N2. The storage capacitor Cst may store electric charges corresponding to a difference between a driving gate electrode voltage of the driving transistor T1 and the initialization voltage Vint.

The hold capacitor Chold may include a third capacitor electrode CE3 and a fourth capacitor electrode CE4. The third capacitor electrode CE3 of the hold capacitor Chold may be electrically connected to the source region of the driving transistor T1 through the second node N2, and the fourth capacitor electrode CE4 of the hold capacitor Chold may be electrically connected to the second reference voltage line RL2. A compensation voltage for compensating for the threshold voltage of the driving transistor T1 may be stored in the hold capacitor Chold.

The specific operation of each subpixel SP according to an embodiment is as follows.

During an initialization period, in case that the initialization signal GI is supplied through the initialization signal line GIL, the initialization transistor T4 is turned on, and the pixel electrode of the organic light-emitting diode OLED is initialized by the initialization voltage Vint supplied from the initialization voltage line VL. As described above, the initialization signal line GIL may be the write signal line GWL in a subpixel which belongs to a next row and is adjacent to the subpixel SP and electrically connected to the same data line DL. For example, the initialization signal GI may be referred to as a next write signal GW (next scan signal).

During a compensation period, in case that the reference voltage signal GR is supplied through the reference voltage signal line GRL, the reference voltage transistor T3 is turned on, and the first reference voltage Vref1 supplied from the first reference voltage line RL1 is transmitted to the driving gate electrode G1 of the driving transistor T1 to compensate for the threshold voltage of the driving transistor T1. A compensation voltage for compensating for the threshold voltage of the driving transistor T1 may be stored in the hold capacitor Chold. As described above, if necessary, the reference voltage signal line GRL may be the write signal line GWL in a subpixel which belongs to a previous row and is adjacent to the subpixel SP and electrically connected to the same data line DL. For example, the reference voltage signal GR may be referred to as a previous write signal GW (previous scan signal).

During a data programming period, in case that the write signal GW is supplied through the write signal line GWL, the switching transistor T2 may be turned on in response to the write signal GW. Then, a voltage corresponding to the data signal DT supplied from the data line DL may be applied to the driving gate electrode G1 of the driving transistor T1. Since the first capacitor electrode CE1 of the storage capacitor Cst is electrically connected to the driving gate electrode G1 of the driving transistor T1 through the first node N1, and the second capacitor electrode CE2 of the storage capacitor Cst may be electrically connected to the third capacitor electrode CE3 of the hold capacitor Chold, which stores a compensation voltage in which the threshold voltage of the driving transistor T1 is compensated for, through the second node N2, the storage capacitor Cst stores a data voltage in which the threshold voltage of the driving transistor T1 is compensated for.

During an emission period, the first emission control transistor T5 may be turned on by the first emission control signal EM supplied from the first emission control line EML. For example, the second emission control transistor T6 may be also turned on by the second emission control signal EMB supplied from the second emission control line EMBL. Since the first capacitor electrode CE1 of the storage capacitor Cst is electrically connected to the driving gate electrode G1 of the driving transistor T1 through the first node N1, and the second capacitor electrode CE2 of the storage capacitor Cst may be electrically connected to the source region of the driving transistor T1 through the second node N2, by the data voltage, in which the threshold voltage of the driving transistor T1 is compensated for, stored in the storage capacitor Cst, a driving current corresponding to the data signal DT flows to the organic light-emitting diode OLED irrespective of the threshold voltage of the driving transistor T1.

As described above, multiple transistors T1 to T6 may include an oxide semiconductor material. Since an oxide semiconductor has high carrier mobility and low leakage current, a voltage drop is not large even in case that an operating time may be long. For example, in the case of the oxide semiconductor, a color change of an image due to a voltage drop is not large even during low-frequency driving, and thus low-frequency driving is possible. Accordingly, multiple transistors T1 to T6 may include the oxide semiconductor material, thereby implementing the display device 10 in which the occurrence of a leakage current is prevented, and simultaneously, power consumption is reduced.

The pixel circuit PC is illustrated in FIG. 3 as including six transistors and two capacitors, but the disclosure is not limited thereto. In another embodiment, the pixel circuit PC may include five transistors and two capacitors. In another embodiment, the pixel circuit PC may include seven transistors and two capacitors. For example, the pixel circuit PC may include more or less than six transistors and more or less than two capacitors.

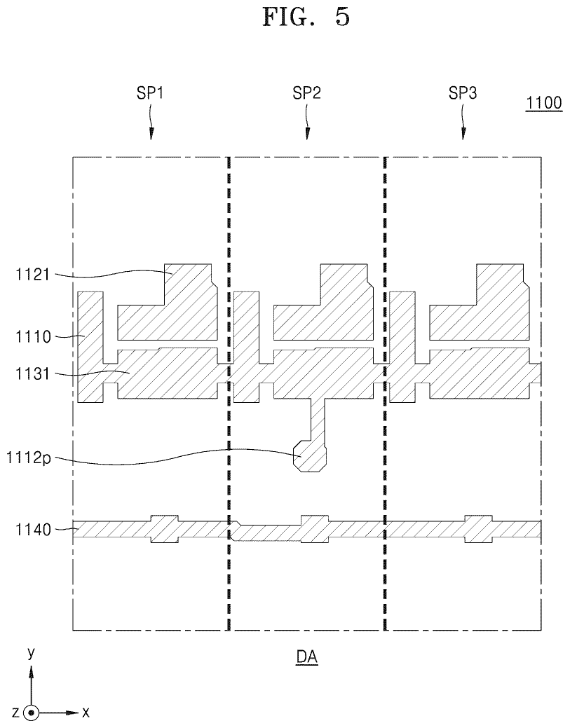

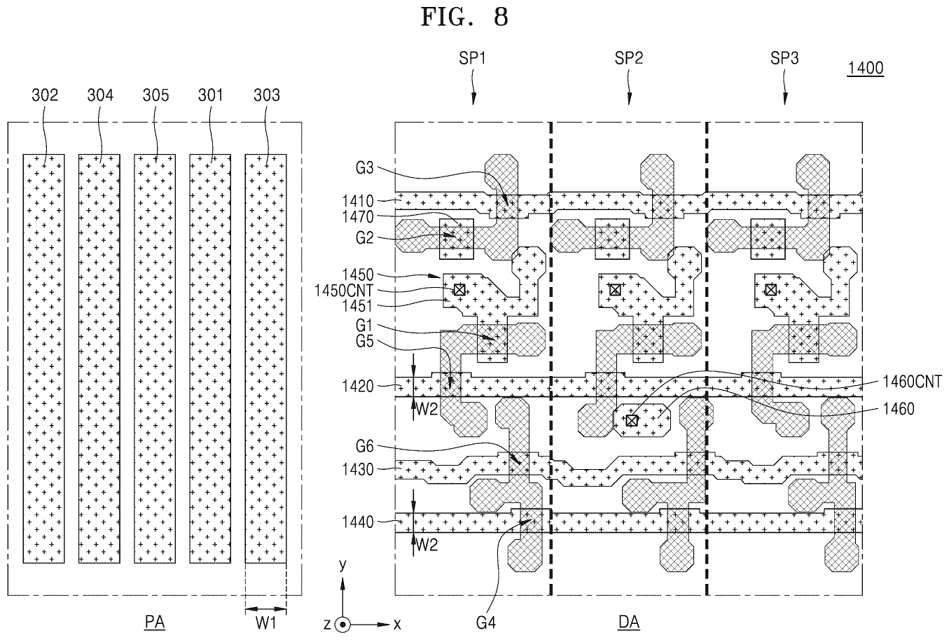

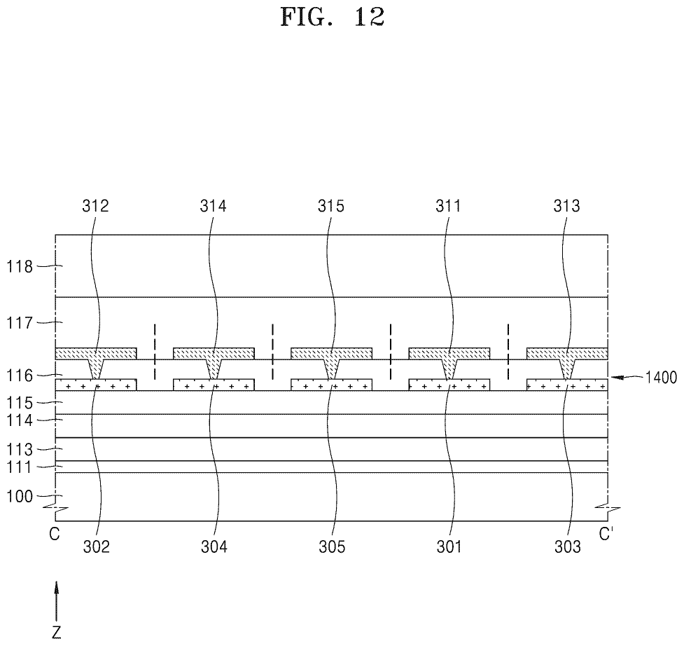

FIG. 4 is a schematic layout illustrating positions of the transistors T1 to T6, the storage capacitor Cst, and the hold capacitor Chold in the pixels included in the display device 10 of FIG. 1. FIGS. 5 to 10 are schematic layouts illustrating, for each layer, components such as the transistors T1 to T6, the storage capacitor Cst, and the hold capacitor Chold of the display device 10 shown in FIG. 4 according to the order of a manufacturing process. FIG. 11 is a schematic cross-sectional view illustrating a cross section taken along continuous line B-B′ of the display device 10 shown in FIG. 4. Meanwhile, FIG. 8 illustrates a layout of the test lines 30 shown in FIG. 2 together with the components of the pixels. FIG. 12 is a schematic cross-sectional view illustrating a cross section taken along discontinuous line C-C′ of the display device 10 shown in FIG. 2. Hereinafter, the display device 10 according to an embodiment of the disclosure will be described in detail with reference to FIGS. 4 to 12. The cross-sectional views of FIGS. 11 and 12 schematically illustrate the components by modifying the components to better illustrate the features of the components.

The display device 10 may include the pixels, and the pixels may be positioned in the display area DA. Each of the pixels may include a first subpixel SP1, a second subpixel SP2, and a third subpixel SP3. For example, the first subpixel SP1 may be a red subpixel that emits red light, the second subpixel SP2 may be a green subpixel that emits green light, and the third subpixel SP3 may be a blue subpixel that emits blue light. The disclosure is not limited thereto, and one pixel may include a smaller number of subpixels or a larger number of subpixels.

The pixels illustrated in FIGS. 4 to 10 may be repeatedly disposed in the first direction (or x-axis direction). The pixels illustrated in FIGS. 4 to 10 may also be repeatedly disposed in the second direction (or y-axis direction) intersecting the first direction.

Each of the first subpixel SP1, the second subpixel SP2, and the third subpixel SP3 may include a pixel circuit. Hereinafter, for convenience of description, some components will be described based on the pixel circuit of the first subpixel SP1, but these components may also be disposed in the pixel circuit of each of the second subpixel SP2 and the third subpixel SP3.

A barrier layer 111 including silicon oxide, silicon nitride, or silicon oxynitride may be positioned on the substrate 100. The barrier layer 111 may planarize an upper surface of the substrate 100.

Referring to FIG. 5, a lower metal layer 1100 (BMLO) may be disposed on the barrier layer 111. The lower metal layer 1100 may include some horizontal power voltage lines 210 (see FIG. 1). The lower metal layer 1100 may include a horizontal second reference voltage line 1110, a first capacitor electrode 1121, a fourth capacitor electrode 1131, and a horizontal repair line 1140. Among these, the horizontal second reference voltage line 1110 may be electrically connected to the fourth capacitor electrode 1131 and may extend substantially in the first direction (or x-axis direction).

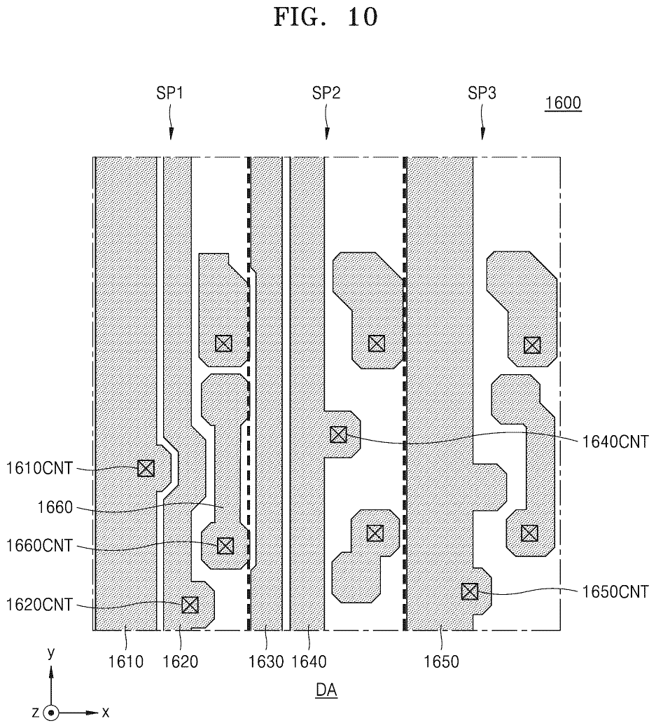

The horizontal second reference voltage line 1110 may be electrically connected to a vertical second reference voltage line 1640 (see FIG. 10) to be described below, which is positioned on the horizontal second reference voltage line 1110 and extends in the second direction (or y-axis direction) intersecting the first direction (or x-axis direction), through a contact hole. The horizontal second reference voltage line 1110 may include a protrusion 1112p protruding in the second direction (or y-axis direction) from the horizontal second reference voltage line 1110 toward the horizontal repair line 1140 in an area of the second subpixel SP2. The horizontal second reference voltage line 1110 may be electrically connected to the vertical second reference voltage line 1640 (see FIG. 10) thereon through a contact hole at the corresponding protrusion 1112p. The horizontal second reference voltage line 1110 and the vertical second reference voltage line 1640 (see FIG. 10) may be components of the second reference voltage line RL2 (see FIG. 3).

The horizontal repair line 1140 may extend in the first direction (or x-axis direction) and may be used in a subsequent pixel repair process.

The first capacitor electrode 1121 may have an isolated shape. The first capacitor electrode 1121 is the first capacitor electrode CE1 of the storage capacitor Cst of FIG. 3. The first capacitor electrode 1121 may be electrically connected to the driving gate electrode G1 (see FIG. 8) of the driving transistor T1 positioned thereon through a contact hole.

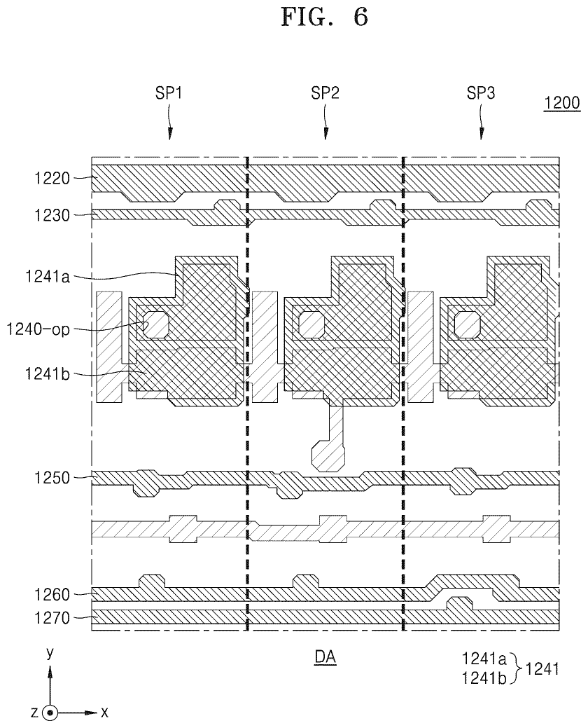

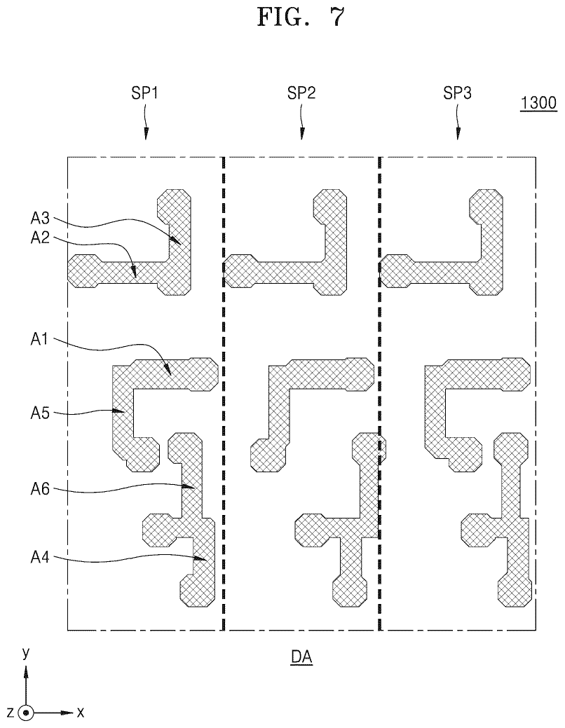

The fourth capacitor electrode 1131 may be electrically connected to the horizontal second reference voltage line 1110. The fourth capacitor electrode 1131 and the horizontal second reference voltage line 1110 are alternately arranged in the first direction (or x-axis direction). The fourth capacitor electrode 1131 may overlap a third capacitor electrode 1241b (see FIG. 6) positioned thereon in a third direction (or z-axis direction). The fourth capacitor electrode 1131 and the third capacitor electrode 1241b (see FIG. 6) are both electrodes of the hold capacitor Chold. Accordingly, the hold capacitor Chold may have a single capacitor structure including the fourth capacitor electrode 1131 of the lower metal layer 1100 and the third capacitor electrode 1241b (see FIG. 6) of an upper metal layer 1200 (see FIG. 6) to be described below as both electrodes. The fourth capacitor electrode 1131 may overlap the driving gate electrode G1 (see FIG. 8) and a driving active region A1 (see FIG. 7) which will be described below. Accordingly, external light may be prevented or minimized from being incident on the driving active region A1. The fourth capacitor electrode 1131 may correspond to the fourth capacitor electrode CE4 of FIG. 3.

The lower metal layer 1100 may include a metal, an alloy, a conductive metal oxide, or the like. For example, the lower metal layer 1100 may include silver (Ag), a silver-containing alloy, molybdenum (Mo), a molybdenum-containing alloy, aluminum (A1), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), or scandium (Sc). The lower metal layer 1100 may have a multilayer structure. For example, the lower metal layer 1100 may have a two-layer structure including an aluminum layer having a thickness of 3,500 angstroms and a titanium layer having a thickness of 300 angstroms.

A first buffer layer 113 (see FIG. 11) may cover the lower metal layer 1100 and may be disposed on the barrier layer 111. The first buffer layer 113 may include an insulating material. For example, the first buffer layer 113 may include silicon oxide, silicon nitride, or silicon oxynitride. The first buffer layer 113 serves to insulate the lower metal layer 1100 from the upper metal layer 1200. The first buffer layer 113 may prevent metal atoms or impurities from the substrate 100 or the like from diffusing into a semiconductor layer 1300 positioned thereon.

The upper metal layer 1200 (BML) as shown in FIG. 6 may be disposed on the first buffer layer 113 in the third direction (or z-axis direction). In FIG. 6, for convenience of description, the lower metal layer 1100 is illustrated together with the upper metal layer 1200. The upper metal layer 1200 may include all the horizontal power voltage lines 210 (see FIG. 1) except for the horizontal second reference voltage line 1110. The upper metal layer 1200 may include a write signal line 1220, a horizontal first reference voltage line 1230, a common capacitor electrode 1241, a horizontal first power line 1250, a horizontal second power line 1270, and a horizontal initialization voltage line 1260. Among these, the write signal line 1220, the horizontal first reference voltage line 1230, the horizontal first power line 1250, the horizontal initialization voltage line 1260, and the horizontal second power line 1270 may extend in the first direction (or x-axis direction).

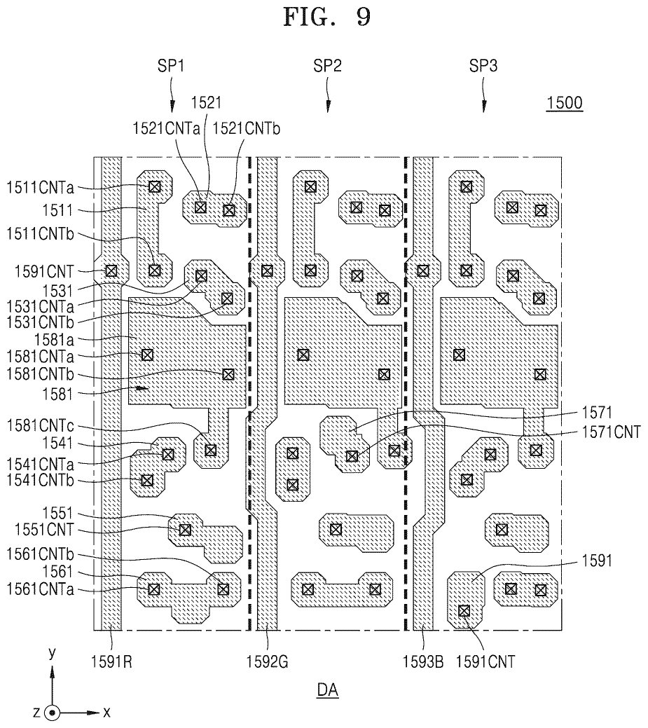

The write signal line 1220 may be an interconnect that applies the write signal GW to the switching transistor T2 and may correspond to the write signal line GWL of FIG. 3. The write signal line 1220 may be electrically connected to the switching gate electrode G2 (see FIG. 4) of the switching transistor T2 through a first connection electrode 1511 (see FIG. 9) of a second conductive layer 1500 (first source/drain layer) to be described below. The write signal line 1220 may include a protrusion protruding in the second direction (or y-axis direction) toward the horizontal first reference voltage line 1230, and a contact hole of the first connection electrode 1511 (see FIG. 9) for connecting the write signal line 1220 to the switching gate electrode G2 (see FIG. 4) may be formed in the protrusion.

The horizontal first reference voltage line 1230 may be electrically connected to a vertical first reference voltage line 1630 (se FIG. 10) to be described below, which is positioned on the horizontal first reference voltage line 1230 and extends in the second direction (or y-axis direction) intersecting the first direction (or x-axis direction), through a contact hole (not shown in FIG. 10). The horizontal first reference voltage line 1230 and the vertical first reference voltage line 1630 (see FIG. 10) may be components of a first reference voltage line. For example, the first reference voltage line corresponds to the first reference voltage line RL1 of FIG. 3. The horizontal first reference voltage line 1230 may be a component belonging to the horizontal power voltage lines 210 shown in FIG. 1.

The horizontal first power line 1250 may be electrically connected to a vertical first power line 1610 (see FIG. 10) to be described below, which is positioned on the horizontal first power line 1250 and extends in the second direction (or y-axis direction) intersecting the first direction (or x-axis direction), through a contact hole. The horizontal first power line 1250 and the vertical first power line 1610 (see FIG. 10) may be components of a first power line that supplies the driving voltage ELVDD to the organic light-emitting diode OLED. For example, the first power line corresponds to the first power line PL2 of FIG. 3. The horizontal first power line 1250 may be a component belonging to the horizontal power voltage lines 210 shown in FIG. 1.

The horizontal initialization voltage line 1260 may be electrically connected to a vertical initialization voltage line 1620 (see FIG. 10) to be described below, which is positioned on the horizontal initialization voltage line 1260 and extends in the second direction (or y-axis direction) intersecting the first direction (or x-axis direction), through a contact hole. The horizontal initialization voltage line 1260 and the vertical initialization voltage line 1620 (see FIG. 10) may be components of an initialization voltage line. The initialization voltage line may correspond to the initialization voltage line VL of FIG. 3. The initialization voltage line may be a component belonging to the horizontal power voltage lines 210 shown in FIG. 1.

The horizontal second power line 1270 may be electrically connected to a vertical second power line 1650 (see FIG. 10) to be described below, which is positioned on the horizontal second power line 1270 and extends in a second direction (or y-axis direction) intersecting the first direction (or x-axis direction), through a contact hole. The horizontal second power line 1270 and the vertical second power line 1650 (see FIG. 10) may be components of a second power line that may be electrically connected to the organic light-emitting diode OLED later to supply a common voltage ELVSS. The horizontal second power line 1270 may be a component belonging to the horizontal power voltage lines 210 shown in FIG. 1.

The common capacitor electrode 1241 may have an isolated shape. The common capacitor electrode 1241 may be the third capacitor electrode CE3 of the hold capacitor Chold of FIG. 3 and may also be a 2-1 capacitor electrode 1241a which is a portion of the second capacitor electrode CE2 of the storage capacitor Cst. Among areas of the common capacitor electrode 1241, a portion, which is close to the horizontal first reference voltage line 1230 which corresponds to an upper portion of the second direction (or y-axis direction), may be the 2-1 capacitor electrode 1241a, and a portion, which is close to the horizontal first power line 1250 which corresponds to a lower portion of the second direction (or y-axis direction), may be a third capacitor electrode. For example, the second capacitor electrode CE2 of the storage capacitor Cst and the third capacitor electrode CE3 of the hold capacitor Chold may be a unified conductive layer.

The common capacitor electrode 1241 may include an opening 1240-op. Through the opening 1240-op, the lower metal layer 1100 and a first conductive layer 1400 (gate layer) to be described below may be electrically connected to each other through a contact hole. The first capacitor electrode 1121 of the storage capacitor Cst of the lower metal layer 1100 may be electrically connected to the driving gate electrode G1 (see FIG. 8) of the driving transistor T1 of the first conductive layer 1400 through the opening 1240-op. The common capacitor electrode 1241 may overlap the driving gate electrode G1 (see FIG. 8) of the first conductive layer 1400 to be described below and the driving active region A1 (see FIG. 7) of the semiconductor layer 1300. Accordingly, the common capacitor electrode 1241 may prevent or minimize external light from being incident on the driving active region A1 (see FIG. 7).

The upper metal layer 1200 may include a metal, an alloy, a conductive metal oxide, or the like. For example, the upper metal layer 1200 may include silver (Ag), a silver-containing alloy, molybdenum (Mo), a molybdenum-containing alloy, aluminum (A1), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), or scandium (Sc). The upper metal layer 1200 may have a multilayer structure. For example, the upper metal layer 1200 may have a two-layer structure including an aluminum layer having a thickness of 3,500 angstroms and a titanium layer having a thickness of 300 angstroms.

A second buffer layer 114 (see FIG. 11) may cover the upper metal layer 1200 and may be disposed on the first buffer layer 113 in the third direction (or z-axis direction). The second buffer layer 114 may include an insulating material. For example, the second buffer layer 114 may include silicon oxide, silicon nitride, or silicon oxynitride. The second buffer layer 114 serves to insulate the upper metal layer 1200 from the semiconductor layer 1300. The second buffer layer 114 may prevent metal atoms or impurities from the substrate 100 or the like from diffusing into the semiconductor layer 1300 positioned thereon.

The semiconductor layer 1300 as shown in FIG. 7 may be disposed on the second buffer layer 114 in the third direction (or z-axis direction). As described above, the semiconductor layer 1300 may include an oxide semiconductor material. For example, the semiconductor layer 1300 may include indium tin gallium zinc oxide (ITGZO) having a thickness of about 300 angstroms. The driving transistor T1, the switching transistor T2, the reference voltage transistor T3, the initialization transistor T4, the first emission control transistor T5, and the second emission control transistor T6 of FIG. 3 may be positioned along the semiconductor layer 1300 as shown in FIG. 7. FIG. 7 illustrates that the semiconductor layer 1300 may include a first portion, a second portion, and a third portion which are spaced apart from each other, a switching active region A2 of the switching transistor T2 and a reference voltage active region A3 of the reference voltage transistor T3 are positioned at the first portion, and the driving active region A1 of the driving transistor T1 and a first emission control active region A5 of the first emission control transistor T5 are positioned at the second portion. An initialization active region A4 of the initialization transistor T4 and a second emission control active region A6 of the second emission control transistor T6 are illustrated as being positioned at the third portion.

A gate insulating layer 115 (see FIG. 11) may cover the semiconductor layer 1300 and may be disposed on the second buffer layer 114. The gate insulating layer 115 may include an insulating material. For example, the gate insulating layer 115 may include an inorganic insulating layer of silicon oxide, silicon nitride, silicon oxynitride, aluminum oxide, or the like.

The first conductive layer 1400 as shown in FIG. 8 may be positioned on the gate insulating layer 115 in the third direction (or z-axis direction). In FIG. 8, for convenience of description, the first conductive layer 1400 may be illustrated together with the semiconductor layer 1300. The first conductive layer 1400 may include a reference voltage signal line 1410 including the reference voltage gate electrode G3, a first emission control line 1420 including the first emission control gate electrode G5, a second emission control line 1430 including the second emission control gate electrode G6, an initialization signal line 1440 including the initialization gate electrode G4, a switching gate electrode layer 1470, and a common gate electrode layer 1450. According to an embodiment of the disclosure, the first conductive layer 1400 further may include the test lines 30 in the peripheral area PA.

The reference voltage signal line 1410 may correspond to the reference voltage signal line GRL of FIG. 3. A portion of the reference voltage signal line 1410 overlapping the semiconductor layer 1300 may be the reference voltage gate electrode G3 of the reference voltage transistor T3. FIG. 8 illustrates that the reference voltage signal line 1410 may include a protrusion, and the protrusion may be the reference voltage gate electrode G3.

The first emission control line 1420 may correspond to the first emission control line EML of FIG. 3. A portion of the first emission control line 1420 overlapping the semiconductor layer 1300 in the third direction (or z-axis direction) may be the first emission control gate electrode G5 of the first emission control transistor T5. FIG. 8 illustrates that the first emission control line 1420 may include a protrusion, and the protrusion may be the first emission control gate electrode G5.

The second emission control line 1430 may correspond to the second emission control line EMBL of FIG. 3. A portion of the second emission control line 1430 overlapping the semiconductor layer 1300 in the third direction (or z-axis direction) may be the second emission control gate electrode G6 of the second emission control transistor T6. FIG. 8 illustrates that the second emission control line 1430 may include a protrusion, and the protrusion may be the second emission control gate electrode G6.

The initialization signal line 1440 may correspond to the initialization signal line GIL of FIG. 3. A portion of the initialization signal line 1440 overlapping the semiconductor layer 1300 in the third direction (or z-axis direction) may be the initialization gate electrode G4 of the initialization transistor T4. FIG. 8 illustrates that the initialization signal line 1440 may include a protrusion, and the protrusion may be the initialization gate electrode G4.

The switching gate electrode layer 1470 may have an isolated shape. A portion of the switching gate electrode layer 1470 may overlap the semiconductor layer 1300 therebelow. A portion of the switching gate electrode layer 1470 overlapping the semiconductor layer 1300 in the third direction (or z-axis direction), for example, a portion overlapping the switching active region A2 of the semiconductor layer 1300, may be referred to as the switching gate electrode G2. The switching gate electrode G2 may be electrically connected to the write signal line 1220 through the first connection electrode 1511 of the second conductive layer 1500 to be described below.

The common gate electrode layer 1450 may have an isolated shape. A portion of the common gate electrode layer 1450 may overlap the semiconductor layer 1300 therebelow. The portion of the common gate electrode layer 1450 overlapping the semiconductor layer 1300, for example, a portion overlapping the driving active region A1 of the semiconductor layer 1300, may be the driving gate electrode G1. Meanwhile, another portion of the common gate electrode layer 1450 may not overlap the semiconductor layer 1300 and may overlap the upper metal layer 1200. The portion of the common gate electrode layers 1450 which does not overlap the semiconductor layer 1300 and overlaps the upper metal layer 1200 may be a capacitor electrode of the storage capacitor Cst. For example, the driving gate electrode G1 of the driving transistor T1 of FIG. 3 and the capacitor electrode of the storage capacitor Cst may be a unified conductive layer. The portion of the common gate electrode layer 1450 corresponding to the capacitor electrode may be a 2-2 capacitor electrode 1451 which is a portion of the second capacitor electrode CE2 of the storage capacitor Cst and may be electrically connected to the first capacitor electrode 1121 through a contact hole 1450CNT. Accordingly, the storage capacitor Cst may have a dual capacitor structure by including the first capacitor electrode 1121 consisting of the lower metal layer 1100, the 2-1 capacitor electrode 1241a consisting of the upper metal layer 1200, and the 2-2 capacitor electrode 1451 consisting of the first conductive layer 1400.

Meanwhile, the driving gate electrode G1 of the driving transistor T1 and the first capacitor electrode 1121 of the storage capacitor Cst may be electrically connected to each other through a contact hole. As described above with reference to FIG. 6, the common capacitor electrode 1241 of the upper metal layer 1200 may include the opening 1240-op. Through the opening 1240-op, the first capacitor electrode 1121 of the lower metal layer 1100 and the driving gate electrode G1 of the first conductive layer 1400 may be electrically connected to each other through a contact hole.

Meanwhile, in FIG. 8, the peripheral area PA in which the test lines 30 of FIG. 1 are positioned is illustrated at a left side of the display area DA, in which the pixels are shown, together therewith. The first conductive layer 1400 may further include the test lines 30. For example, the test lines 30 may be positioned on a gate layer. The test lines 30 may extend substantially in the second direction (or y-axis direction). The test lines 30 shown in FIG. 8 may correspond to the first power test line 301, the second power test line 302, the initialization voltage test line 303, the first reference voltage test line 304, and the second reference voltage test line 305 shown in FIG. 2, respectively. A width W1 of each of the test lines 30 in the first direction (or x-axis direction) may be greater than a width W2 of each of the signal lines of the display area DA in the second direction (or y-axis direction). The test lines 30 may be interconnects that supply a power voltage and thus may have a wider width than the signal lines that supply a signal, thereby preventing a voltage drop.

According to an embodiment of the disclosure, the test lines 30 may be formed before the vertical power voltage lines 220 (see FIG. 1) are formed. The test lines 30 may be formed before the vertical power voltage lines 220 and may be electrically connected to the horizontal power voltage lines 210. Accordingly, the test lines 30 and the horizontal power voltage lines 210 may implement a global mesh form in the entire area of the display device 10. Due to the global mesh form, the display device 10 may be subject to an FCA test even before the vertical power voltage lines 220 are formed.

This first conductive layer 1400 may include a metal, an alloy, a conductive metal oxide, a transparent conductive material, or the like. For example, the first conductive layer 1400 may include silver (Ag), a silver-containing alloy, molybdenum (Mo), a molybdenum-containing alloy, aluminum (AI), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), or indium zinc oxide (IZO). The first conductive layer 1400 may have a multilayer structure. For example, the first conductive layer 1400 may have a two-layer structure including a titanium layer having a thickness of 300 angstroms and a molybdenum layer having a thickness of 2,500 angstroms. The first conductive layer 1400 may also be referred to as a gate layer.

An interlayer insulating layer 116 (see FIG. 11) may cover the first conductive layer 1400 and may be positioned on the gate insulating layer 115 in the third direction (or z-axis direction). The interlayer insulating layer 116 may include an insulating material. For example, the interlayer insulating layer 116 may include silicon oxide, silicon nitride, silicon oxynitride, aluminum oxide, or the like.

The second conductive layer 1500 as shown in FIG. 9 may be positioned on the interlayer insulating layer 116 in the third direction (or z-axis direction). The second conductive layer 1500 may include data lines 1591R, 1592G, and 1593B, a first connection electrode 1511, a second connection electrode 1521, a third connection electrode 1531, a fourth connection electrode 1541, a fifth connection electrode 1551, a sixth connection electrode 1561, a seventh connection electrode 1571, and a common source/drain electrode layer 1581. The second conductive layer 1500 may also be referred to as a first source/drain layer.

At least one of the data lines 1591R, 1592G, and 1593B may correspond to the data line DL of FIG. 3. The data lines 1591R, 1592G, and 1593B may extend in the second direction (or y-axis direction). The data lines 1591R, 1592G, and 1593B are disposed for each subpixel. An R data line 1591R that transmits a data signal for emitting red light is positioned in the first subpixel SP1, a G data line 1592G that transmits a data signal for emitting green light is positioned in the second subpixel SP2, and a B data line 1593B that transmits a data signal for emitting blue light may be positioned in the third subpixel SP3. The data line may be electrically connected to one side of the switching active region A2 of the semiconductor layer 1300 therebelow through a contact hole.

Each of the first connection electrode 1511, the second connection electrode 1521, the third connection electrode 1531, the fourth connection electrode 1541, the fifth connection electrode 1551, and the sixth connection electrode 1561 may have an isolated shape. The first connection electrode 1511, the second connection electrode 1521, the third connection electrode 1531, the fourth connection electrode 1541, the fifth connection electrode 1551, and the sixth connection electrode 1561 are connected to other components thereon or therebelow through contact holes.

The first connection electrode 1511 may be electrically connected to the switching active region A2 of the semiconductor layer 1300 therebelow through a contact hole 1511CNTb. The first connection electrode 1511 may be electrically connected to the write signal line 1220 of the upper metal layer 1200 through a contact hole 1511CNTa. The first connection electrode 1511 serves to connect the write signal line GWL to the switching transistor T2 of FIG. 3.

The second connection electrode 1521 may be electrically connected to the reference voltage active region A3 of the semiconductor layer 1300 through a contact hole 1521CNTa. The second connection electrode 1521 may be electrically connected to the horizontal first reference voltage line 1230 of the upper metal layer 1200 through a contact hole 1521CNTb. The second connection electrode 1521 serves to connect the reference voltage signal line GRL to the reference voltage transistor T3 of FIG. 3.

The third connection electrode 1531 may be electrically connected to a portion between the switching active region A2 and the reference voltage active region A3 of the semiconductor layer 1300 through a contact hole 1531CNTa. The third connection electrode 1531 may be electrically connected to the driving gate electrode G1 of the driving transistor T1 through a contact hole 1531CNTb. For example, the third connection electrode 1531 that electrically connects the switching transistor T2, the reference voltage transistor T3, and the driving transistor T1 may be understood to serve as the first node N1 of FIG. 3.

The fourth connection electrode 1541 may be electrically connected to the first emission control active region A5 of the semiconductor layer 1300 through a contact hole 1541CNTa. The fourth connection electrode 1541 may be electrically connected to the horizontal first power line 1250 of the upper metal layer 1200 through a contact hole 1541CNTb. The fourth connection electrode 1541 serves to connect the first power line PL2 to the first emission control transistor T5 of FIG. 3.

The fifth connection electrode 1551 may be electrically connected to the second emission control active region A6 and the initialization active region A4 of the semiconductor layer 1300 through a contact hole 1551CNT. For example, the fifth connection electrode 1551 electrically connecting the second emission control transistor T6 to the initialization transistor T4 may be understood to serve as the third node N3 of FIG. 3.

The sixth connection electrode 1561 may be electrically connected to the initialization active region A4 of the semiconductor layer 1300 through a contact hole 1561CNTb. The sixth connection electrode may be electrically connected to the horizontal initialization voltage line 1260 of the upper metal layer 1200 through a contact hole 1561CNTa. The sixth connection electrode 1561 serves to connect the initialization signal line GIL to the initialization transistor T4 of FIG. 3.

The common source/drain electrode layer 1581 may have an isolated shape.

The common source/drain electrode layer 1581 may overlap the common gate electrode layer 1450 of the first conductive layer 1400 therebelow. The common source/drain electrode layer 1581 also may overlap the common capacitor electrode 1241 of the upper metal layer 1200 therebelow and may be electrically connected to the common capacitor electrode 1241 of the upper metal layer 1200 through a contact hole 1581CNTa. The common source/drain electrode layer 1581 also may overlap the first capacitor electrode 1121 of the lower metal layer 1100 therebelow. The common source/drain electrode layer 1581 may be a 2-3 capacitor electrode 1581a that is a portion of the second capacitor electrode CE2 of the storage capacitor Cst. Accordingly, the storage capacitor Cst may have a triple capacitor structure by including the first capacitor electrode 1121 consisting of the lower metal layer 1100, the 2-1 capacitor electrode 1241a consisting of the upper metal layer 1200, the 2-2 capacitor electrode 1451 consisting of the first conductive layer 1400, and the 2-3 capacitor electrode 1581a consisting of the second conductive layer 1500. The common source/drain electrode layer 1581 may be electrically connected to the driving active region A1 of the semiconductor layer 1300 through a contact hole 1581CNTb. The common source/drain electrode layer 1581 may include a protrusion and may be electrically connected to the second emission control active region A6 of the semiconductor layer 1300 through a contact hole 1581CNTc of the protrusion. For example, the fifth connection electrode 1543 electrically connecting the second emission control transistor T6, the driving transistor T1, and the storage capacitor Cst may be understood to serve as the second node N2 of FIG. 3.

Meanwhile, the second subpixel SP2 adjacent to the first subpixel SP1 is provided with the seventh connection electrode 1571. The seventh connection electrode 1571 also may have an isolated shape. The seventh connection electrode 1571 electrically connects the horizontal second reference voltage line 1110 of the lower metal layer 1100 to the vertical second reference voltage line 1640 (see FIG. 10) of a third conductive layer 1600 (see FIG. 10, second source/drain layer) later. The seventh connection electrode 1571 may be electrically connected to an eighth connection electrode 1460 of the first conductive layer 1400 of FIG. 8 through a contact hole 1571CNT. The eighth connection electrode 1460 of the first conductive layer 1400 of FIG. 8 may be electrically connected to the horizontal second reference voltage line 1110 of the protrusion 1112p of the lower metal layer 1100 through a contact hole 1460CNT. The vertical second reference voltage line 1640 of the third conductive layer 1600 (see FIG. 10, second source/drain layer) of FIG. 10 may be electrically connected to the seventh connection electrode 1571 of the second conductive layer 1500 (see FIG. 9, first source/drain layer) through a contact hole 1640CNT. For example, the seventh connection electrode 1571 serves to electrically connect the horizontal second reference voltage line 1110 to the vertical second reference voltage line 1640.

Meanwhile, referring to FIGS. 1, 2, and 12, the second conductive layer 1500 may further include the connection interconnects 31. The connection interconnects 31 are arranged in the peripheral area PA, may extend in the first direction (or x-axis direction), and electrically connect the test lines 30 to the horizontal power voltage lines 210.

The connection interconnects 31 may be positioned on a different layer from the test lines 30. For example, one ends of the connection interconnects 31 of the second conductive layer 1500 are respectively connected to the test lines 30 respectively corresponding to the connection interconnects 31 through contact holes. For example, the first connection interconnect 311 may be electrically connected to the first power test line 301 through a contact hole. The second connection interconnect 312 may be electrically connected to the second power test line 302 through a contact hole. The third connection interconnect 313 may be electrically connected to the initialization voltage test line 303 through a contact hole. The fourth connection interconnect 314 may be electrically connected to the first reference voltage test line 304 through a contact hole. The fifth connection interconnect 315 may be electrically connected to the second reference voltage test line 305 through a contact hole. The other ends of the connection interconnects 31 of the second conductive layer 1500 are connected to the horizontal power voltage lines 210 through contact holes. For example, the first connection interconnect 311 may be electrically connected to the horizontal first power line 1250 of the upper metal layer 1200 through a contact hole.

The second connection interconnect 312 may be electrically connected to the horizontal second power line 1270 of the upper metal layer 1200 through a contact hole. The third connection interconnect 313 may be electrically connected to the horizontal initialization voltage line 1260 of the upper metal layer 1200 through a contact hole. The fourth connection interconnect 314 may be electrically connected to the horizontal first reference voltage line 1230 of the upper metal layer 1200 through a contact hole. The fifth connection interconnect 315 may be electrically connected to the horizontal second reference voltage line 1110 of the lower metal layer 1100 through a contact hole.

The connection interconnects 31 may be positioned on the same layer as the test lines 30. For example, the connection interconnects 31 are formed integrally with the test lines 30 without needing to be electrically connected to the test lines 30 through contact holes.

Meanwhile, multiple connection interconnects 31 may be positioned on different layers. For example, the first connection interconnect 311 and the second connection interconnect 312 may be positioned on the first conductive layer 1400, but the third to fifth connection interconnects 313 to 315 may be positioned on the second conductive layer 1500. The position and shape of each of the connection interconnects 31 may be varied in various ways.

The second conductive layer 1500 may include a metal, an alloy, a conductive metal oxide, a transparent conductive material, or the like. For example, the second conductive layer 1500 may include silver (Ag), a silver-containing alloy, molybdenum (Mo), a molybdenum-containing alloy, aluminum (AI), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, or IZO. For example, the second conductive layer 1500 may have a multilayer structure including a titanium layer with a thickness of 700 angstroms, an aluminum layer with a thickness of 6,000 angstroms, and a titanium layer with a thickness of 300 angstroms.

A first planarization layer 117 (see FIG. 11) may cover the second conductive layer 1500 and may be positioned on the interlayer insulating layer 116. The first planarization layer 117 may include an insulating material. For example, the first planarization layer 117 may include silicon oxide, silicon nitride, silicon oxynitride, aluminum oxide, or the like.

The third conductive layer 1600 as shown in FIG. 10 may be positioned on the first planarization layer 117. The third conductive layer 1600 may include the vertical power voltage lines 220. The vertical power voltage lines 220 may include the vertical first power line 1610, the vertical initialization voltage line 1620, the vertical first reference voltage line 1630, the vertical second reference voltage line 1640, the vertical second power line 1650, and a tenth connection electrode 1660. Each of the vertical first power line 1610, the vertical initialization voltage line 1620, the vertical first reference voltage line 1630, the vertical second reference voltage line 1640, and the vertical second power line 1650 may have a shape extending approximately in the second direction (or y-axis direction).

The vertical first power line 1610 traverses the first subpixel SP1 in the second direction (or y-axis direction). The vertical first power line 1610 may be electrically connected to the fourth connection electrode 1541 of the lower second conductive layer 1500 through a contact hole 1610CNT. The fourth connection electrode 1541 may be electrically connected to the horizontal first power line 1250 of the upper metal layer 1200 through the contact hole 1541CNTb. For example, the vertical first power line 1610 of the third conductive layer 1600 may be electrically connected to the horizontal first power line 1250 of the upper metal layer 1200. The vertical first power line 1610 and the horizontal first power line 1250 electrically connected to each other may form the first power line. A structure of the first power line may be applied to all of multiple pixels arranged in a matrix form in the display area DA. Therefore, the first power line may be implemented in a mesh form in the display area DA. The first power line may supply the first power voltage ELVDD to the pixel.

The vertical initialization voltage line 1620 traverses the first subpixel SP1 in the second direction (or y-axis direction). The vertical initialization voltage line 1620 may be electrically connected to the sixth connection electrode 1561 of the second conductive layer 1500 therebelow through a contact hole 1620CNT. The sixth connection electrode 1561 may be electrically connected to the horizontal initialization voltage line 1260 of the upper metal layer 1200 through the contact hole 1561CNTa. For example, the vertical initialization voltage line 1620 of the third conductive layer 1600 may be electrically connected to the horizontal initialization voltage line 1260 of the upper metal layer 1200. The vertical initialization voltage line 1620 and the horizontal initialization voltage line 1260 electrically connected to each other may form the initialization voltage line. A structure of the initialization voltage line may be applied to all of multiple pixels arranged in a matrix form in the display area DA. Therefore, the initialization voltage line may be implemented in a mesh form in the display area DA. The initialization voltage line may supply the initialization voltage Vint to the pixel.

The vertical first reference voltage line 1630 traverses the second subpixel SP2 adjacent to the first subpixel SP1 in the second direction (or y-axis direction). Although not shown in FIG. 10, the vertical first reference voltage line 1630 may be electrically connected to the horizontal first reference voltage line 1230 of the lower metal layer 1100 therebelow through a contact hole (not shown). For example, the vertical first reference voltage line 1630 of the third conductive layer 1600 may be electrically connected to the horizontal first reference voltage line 1230 of the lower metal layer 1100. The vertical first reference voltage line 1630 and the horizontal first reference voltage line 1230 electrically connected to each other may form the first reference voltage line. A structure of the first reference voltage line may be applied to all of multiple pixels arranged in a matrix form in the display area DA. Therefore, the first reference voltage line may be implemented in a mesh form in the display area DA. The first reference voltage line may supply the first reference voltage Vref1 to the pixel.

The vertical second reference voltage line 1640 traverses the second subpixel SP2 adjacent to the first subpixel SP1 in the second direction (or y-axis direction). The vertical second reference voltage line 1640 may include a protrusion and may be electrically connected to the seventh connection electrode 1571 of the second conductive layer 1500 therebelow through a contact hole 1640CNT of the protrusion. The seventh connection electrode 1571 may be electrically connected to the eighth connection electrode 1460 of the first conductive layer 1400 of FIG. 8 through the contact hole 1571CNT. The eighth connection electrode 1460 of FIG. 8 may be electrically connected to the horizontal second reference voltage line 1110 of a protrusion of the lower metal layer 1100 through the contact hole 1460CNT. For example, the vertical second reference voltage line 1640 of the third conductive layer 1600 may be electrically connected to the horizontal second reference voltage line 1110 of the lower metal layer 1100. The vertical second reference voltage line 1640 and the horizontal second reference voltage line 1110 electrically connected to each other may form a second reference voltage line. A structure of the second reference voltage line may be applied to all of multiple pixels arranged in a matrix form in the display area DA. Therefore, the second reference voltage line may be implemented in a mesh form in the display area DA. The second reference voltage line may supply the second reference voltage Vref2 to the pixel.

The vertical second power line 1650 traverses the third subpixel SP3 adjacent to the second subpixel SP2 in the second direction (or y-axis direction). The vertical second power line 1650 may include a protrusion and may be electrically connected to a ninth connection electrode 1591 of the second conductive layer 1500 therebelow through a contact hole 1650CNT of the protrusion. The ninth connection electrode 1591 may be electrically connected to the horizontal second power line 1270 of the upper metal layer 1200 through a contact hole 1591CNT. For example, the vertical second power line 1650 of the third conductive layer 1600 may be electrically connected to the horizontal second power line 1270 of the upper metal layer 1200. The vertical second power line 1650 and the horizontal second power line 1270 electrically connected to each other may form the second power line. A structure of the second power line may be applied to all of multiple pixels arranged in a matrix form in the display area DA. Therefore, the second power line may be implemented in a mesh form in the display area DA. The second power line may be electrically connected to the counter electrode 530 (see FIG. 11) of the organic light-emitting diode OLED outside the display area DA and may supply the second power voltage ELVSS to the organic light-emitting diode OLED.

The third conductive layer 1600 may further include the tenth connection electrode 1660. The tenth connection electrode 1660 may have an isolated shape. The tenth connection electrode 1660 may be disposed in each subpixel. The tenth connection electrode 1660 may be electrically connected to the fifth connection electrode 1551 of the second conductive layer 1500 therebelow through a contact hole 1660CNT. The fifth connection electrode 1551 may be electrically connected to the second emission control active region A6 and the initialization active region A4 of the semiconductor layer 1300 therebelow through the contact hole 1551CNT. Meanwhile, the tenth connection electrode 1660 may be electrically connected to the pixel electrode 510 (see FIG. 11), which is formed on an insulating layer (pixel definition film, see 119 of FIG. 11) covering the third conductive layer 1600, through a via hole (not shown) later.

The third conductive layer 1600 may include a metal, an alloy, a conductive metal oxide, a transparent conductive material, or the like. For example, the third conductive layer 1600 may include silver (Ag), a silver-containing alloy, molybdenum (Mo), a molybdenum-containing alloy, aluminum (AI), an aluminum-containing alloy, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), ITO, or IZO. For example, the third conductive layer 1600 may have a multilayer structure including a titanium layer with a thickness of 700 angstroms, an aluminum layer with a thickness of 6,000 angstroms, and a titanium layer with a thickness of 300 angstroms. The third conductive layer 1600 may also be referred to as the second source/drain layer.

A second planarization layer 118 may cover the third conductive layer 1600 and may be positioned on the first planarization layer 117 in the third direction (or z-axis direction). The second planarization layer 118 may include an organic insulating material. For example, the second planarization layer 118 may include a photoresist, benzocyclobutenea (BCB), polyimide, hexamethyldisiloxane (HMDSO), polymethylmethacrylate (PMMA), polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or a mixture thereof. For example, the second planarization layer 118 may include a polyimide layer with a thickness of about 1.6 μm.

The organic light-emitting diode OLED may be positioned on the second planarization layer 118. The organic light-emitting diode OLED may include the pixel electrode 510, an intermediate layer 520 including an emission layer, and the counter electrode 530.

The pixel electrode 510 may be a (semi-) light-transmitting electrode or a reflective electrode. For example, the pixel electrode 510 may include a reflective layer including at least one selected from Ag, Mg, A1, Pt, Pd, Au, Ni, Nd, Ir, Cr, and a compound thereof, and a transparent or semitransparent electrode layer positioned on the reflective layer. The transparent or semitransparent electrode layer may include at least one selected from the group consisting of ITO, IZO, zinc oxide (ZnO), indium oxide (In₂O₃), indium gallium oxide (IGO), and aluminum zinc oxide (AZO). For example, the pixel electrode 510 may have a three-layer structure of ITO/Ag/ITO.

The pixel definition film 119 may be disposed on the second planarization layer 118 in the third direction (or z-axis direction). The pixel definition film 119 may increase a distance between an edge of the pixel electrode 510 and the counter electrode 530 above the pixel electrode 510, thereby serving to prevent an arc or the like from occurring at the edge of the pixel electrode 510. The pixel definition film 119 may be formed through a method including spin coating using at least one organic insulating material selected from the group consisting of polyimide, polyamide, an acrylic resin, BCB, and a phenol resin.

At least a portion of the intermediate layer 520 of the organic light-emitting diode OLED may be positioned in an opening formed by the pixel definition film 119. An emission area of the organic light-emitting diode OLED may be defined by an opening.

The intermediate layer 520 may include the emission layer. The emission layer may include an organic material including a fluorescent or phosphorescent material that emits red, green, blue, or white light. The emission layer may include a low molecular weight organic material or a high molecular weight organic material, and functional layers such as a hole transport layer (HTL), a hole injection layer (HIL), an electron transport layer (ETL), and an electron injection layer (EIL) may be optionally further disposed below and above the emission layer.

The emission layer may have a patterned shape corresponding to each of the pixel electrodes 510. Layers other than the emission layer included in the intermediate layer 520 may be modified in various ways such as being integrally formed over multiple pixel electrodes 510.

The counter electrode 530 may be a light-transmitting electrode or a reflective electrode. For example, the counter electrode 530 may be a transparent or semitransparent electrode and may include a metal thin film of a metal having a low work function, including as at least one selected from Li, Ca, LiF, A1, Ag, Mg, and a compound thereof. The counter electrode 530 may further include a transparent conductive oxide (TCO) film which is positioned on the metal thin film and is made of ITO, IZO, ZnO, or In₂O₃. The counter electrode 530 may be formed integrally on an entire surface of the display area DA and disposed on the intermediate layer 520 and the pixel definition film 119.

So far, the description has been provided based on the configuration of the first subpixel SP1, but the description may also be applied to the second subpixel SP2 and/or the third subpixel SP3.

The display device 10 according to the embodiment may include the horizontal power voltage lines 210 which are disposed in the display area DA, are positioned on the lower metal layer 1100 or the upper metal layer 1200, and extend in the first direction (or x-axis direction), and the vertical power voltage lines 220 which are disposed in the display area DA, are positioned on the third conductive layer 1600, and extend in the second direction (or y-axis direction) intersecting the first direction (or x-axis direction). For example, the horizontal power voltage lines 210 and the vertical power voltage lines 220 may be electrically connected to each other so that the power voltage lines 200 implement a mesh form in the display area DA. The display device 10 may include the test lines 30 which are disposed in the peripheral area PA of the display area DA, are positioned on a different layer from the vertical power voltage lines 220, are positioned in the layer closer to the substrate 100 than the layer on which the vertical power voltage lines 220 are positioned, and extend in the second direction. For example, the test lines 30 may be electrically connected to the horizontal power voltage lines 210 to implement a global mesh form in the peripheral area PA. The test lines 30 are formed before the vertical power voltage lines 220 are formed. Therefore, the entire display area DA may be driven even before the vertical power voltage lines 220 are formed. Due to the test lines 30, defects of the pixel circuit may be tested before the third conductive layer 1600 is formed.

The horizontal power voltage lines 210 are formed on the lower metal layer 1100 or the upper metal layer 1200 which is positioned below the semiconductor layer 1300. The horizontal power voltage lines 210 are formed before the semiconductor layer 1300, thereby allowing a free interconnect design. The semiconductor layer 1300 may include an oxide semiconductor material. The oxide semiconductor may be sensitive to light, and thus a current amount or the like may be changed due to external light. Therefore, in case that a metal layer is positioned below the oxide semiconductor, the metal layer may absorb or reflect external light. To this end, capacitor electrodes are formed with the lower metal layer 1100 and the upper metal layer 1200, and the capacitor electrodes may be disposed to overlap a semiconductor layer of a driving transformer.

In a method of manufacturing the display device 10 according to the embodiment, in an operation (a),a substrate including a display area DA and a peripheral area PA may be prepared, in an operation (b), horizontal power voltage lines 210, which are disposed in the display area DA and extend in a first direction (or x-axis direction) may be formed. Next, in an operation (c), test lines 30, which are disposed in the peripheral area PA, extend in a second direction (or y-axis direction), and are electrically connected to the horizontal power voltage lines 210, may be formed. Thereafter, in an operation (d), vertical power voltage lines 220, which are disposed in the display area DA, are positioned on a different layer from the horizontal power voltage lines 210 and the test lines 30, extend in the second direction (or y-axis direction), and are electrically connected to the horizontal power voltage lines 210, may be formed, thereby manufacturing the display device 10.

For example, operation (c) may be performed after operation (b). For example, in case that the horizontal power voltage lines 210 and the test lines 30 are positioned on different layers, and the horizontal power voltage lines 210 are positioned on a layer closer to the substrate 100 than the test lines 30, operation (c) may be performed after operation (b).

For example, operations (b) and (c) may be performed simultaneously. For example, in case that at least one of the horizontal power voltage lines 210 and the test lines 30 are positioned on the same layer, operations (b) and (c) may be performed simultaneously.

For example, operation (b) may be performed after operation (c). For example, in case that the horizontal power voltage lines 210 and the test lines 30 are positioned in different layers, and the test lines 30 are positioned on a layer closer to the substrate 100 than at least one of the horizontal power voltage lines 210, operation (b) may be performed after operation (c).

The test lines 30 according to the embodiment of FIGS. 4 to 12 may be positioned on a first conductive layer 1400. For example, the test lines 30 may be positioned on a gate layer.

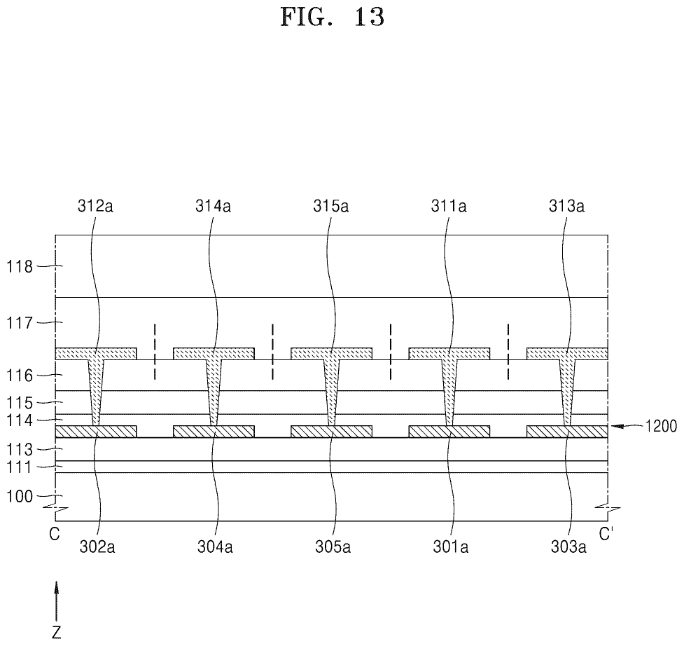

FIGS. 13 to 16 are schematic cross-sectional views illustrating a cross section taken along discontinuous line C-C′ of the display device shown in FIG. 2 according to another embodiment of the disclosure.

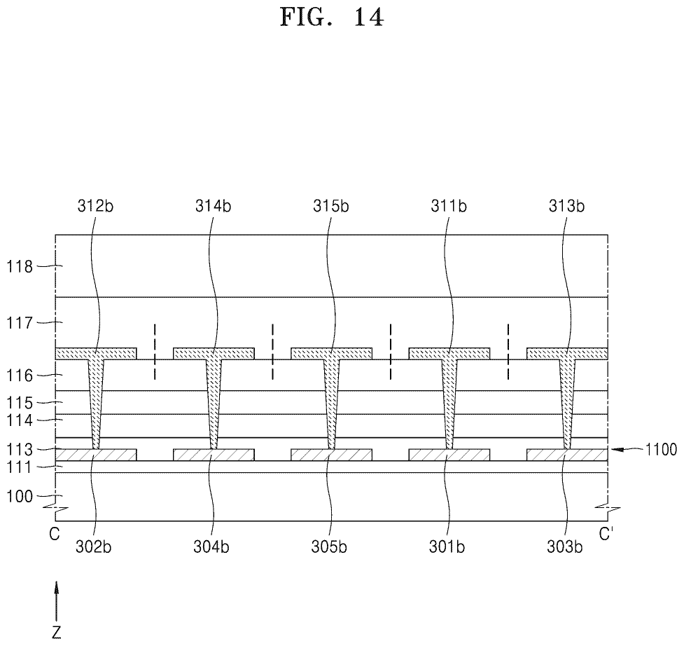

The test lines 30 may be positioned on the same layer as at least one of horizontal power voltage lines 210. For example, referring to FIG. 13, the test lines 30 including a second power test line 302a, a first reference voltage test line 304a, a second reference voltage test line 305a, a first power test line 301a, an initialization voltage test line 303a, a second connection interconnect 312a, a fourth connection interconnect 314a, a fifth connection interconnect 315a, a first connection interconnect 311a, and a third connection interconnect 313a may be positioned on an upper metal layer 1200. For example, the test lines 30 may be positioned on the same layer as a horizontal first power line 1250, a write signal line 1220, a horizontal first reference voltage line 1230, a horizontal second power line 1270, and a horizontal initialization voltage line 1260 positioned on the upper metal layer 1200. Referring to FIG. 14, the test lines 30 including a second power test line 302b, a first reference voltage test line 304b, a second reference voltage test line 305b, a first power test line 301b, an initialization voltage test line 303b, a second connection interconnect 312b, a fourth connection interconnect 314b, a fifth connection interconnect 315b, a first connection interconnect 311b, and a third connection interconnect 313b may be positioned on a lower metal layer 1100. For example, the test lines 30 may be positioned on the same layer as a horizontal second reference voltage line 1110 positioned on the lower metal layer 1100.

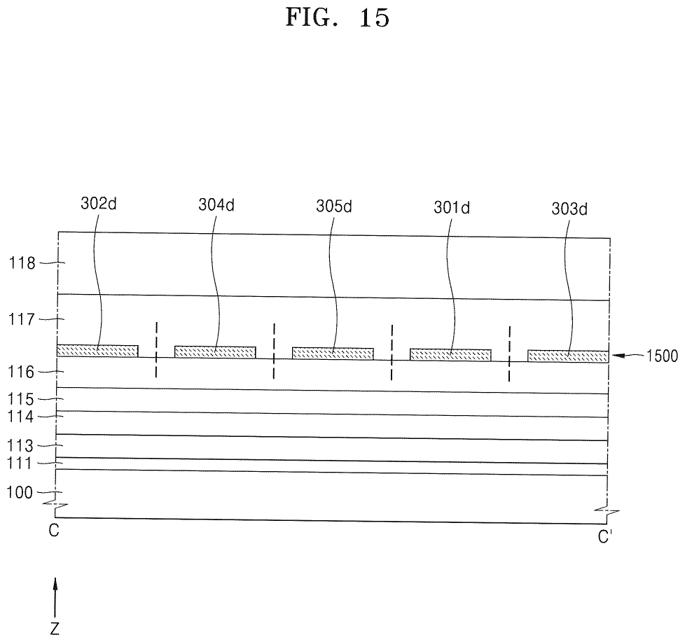

In another embodiment, the test lines 30 may be positioned directly below vertical power voltage lines 220 with an insulating layer interposed therebetween. For example, referring to FIG. 15, the test lines 30 including a second power test line 302d, a first reference voltage test line 304d, a second reference voltage test line 305d, a first power test line 301d, and an initialization voltage test line 303d may be positioned on a second conductive layer 1500. For example, the test lines 30 may be positioned on the same layer as data lines and source/drain electrodes of transistors.

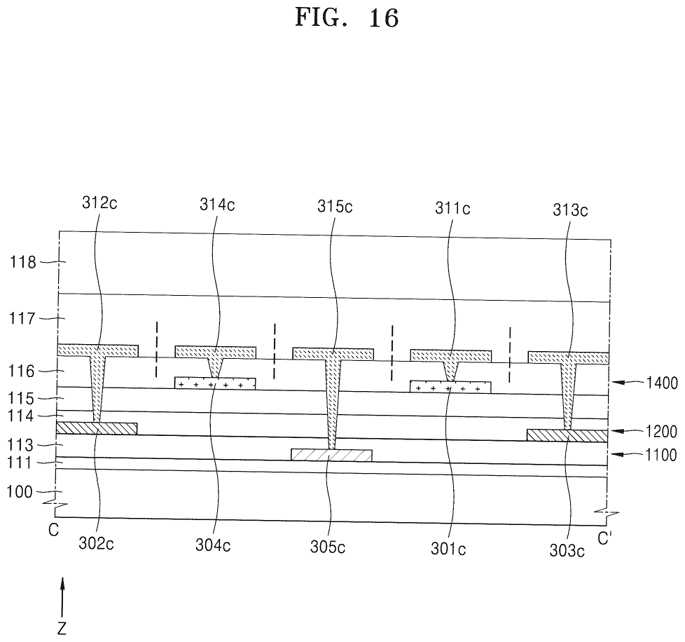

As described above, the test lines 30 may include multiple test lines 30 connected to correspond to each of multiple horizontal power voltage lines 210. As shown in FIGS. 12 to 15, multiple test lines 30 may be positioned on the same layer. However, the disclosure is not limited thereto, and as shown in FIG. 16, multiple test lines 30 including a second power test line 302c, a first reference voltage test line 304c, a second reference voltage test line 305c, a first power test line 301c, an initialization voltage test line 303c, a second connection interconnect 312c, a fourth connection interconnect 314c, a fifth connection interconnect 315c, a first connection interconnect 311c, and a third connection interconnect 313c may be positioned on different layers. For example, referring to FIG. 16, the second power test line 302c may be positioned on the upper metal layer 1200, the first reference voltage test line 304c may be positioned on a first conductive layer 1400, the second reference voltage test line 305c may be positioned on the lower metal layer 1100, the first power test line 301c may be positioned on the first conductive layer 1400, and the initialization voltage test line 303c may be positioned on the upper metal layer 1200. However, FIG. 16 may be an example, and the disclosure may be modified in various ways.

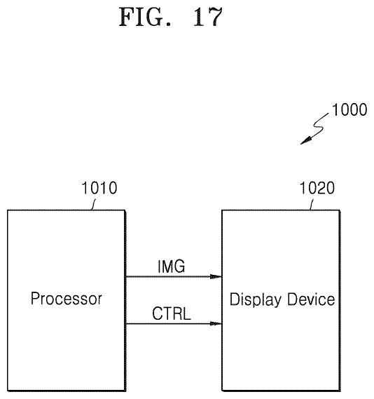

Referring to FIG. 17, the display system 1000 may include a processor 1010 and a display device 1020.

The processor 1010 may perform various tasks and calculations. The processor 1010 may include an application processor, a graphics processor, a microprocessor, a central processing unit (CPU), and the like. The processor 1010 may be electrically connected to other components of the display system 1000 through a bus system to control the other components.

The processor 1010 may transmit image data IMG and a control signal CTRL to the display device 1020. The display device 1020 may display an image based on the image data IMG and the control signal CTRL. The display device 1020 may be similarly configured to the display device 10 described with reference to FIG. 1.

The display system 1000 may include a computing system providing an image display function, such as a smart watch, a mobile phone, a smart phone, a portable computer, a tablet personal computer (PC), a watch phone, an automotive display, smart glasses, a portable multimedia player (PMP), a navigation device, and an ultra mobile personal computer (UMPC). The display system 1000 may include at least one of a head mounted display (HMD) device, a virtual reality (VR) device, a mixed reality (MR) device, and an augmented reality (AR) device.

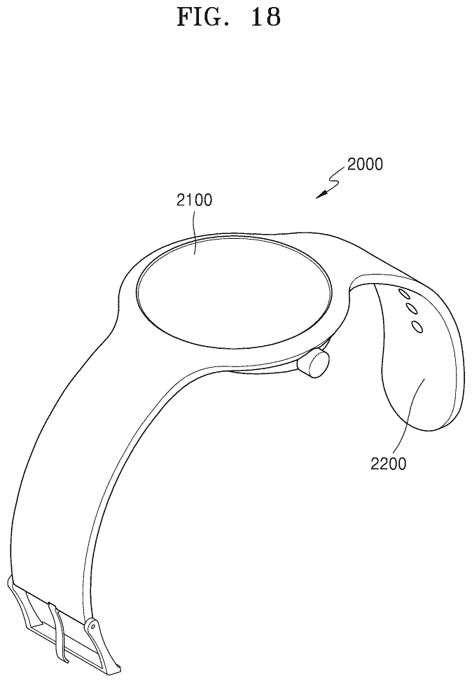

Referring to FIG. 18, the display system 1000 of FIG. 17 may be applied to a smart watch 2000 including a display unit 2100 and a strap unit 2200.

The smart watch 2000 may be a wearable electronic device. For example, the smart watch 2000 may have a structure in which the strap unit 2200 is mounted on a user's wrist. Here, the display system 1000 and/or the display device 1020 may be applied to the display unit 2100, and image data including time information may be provided to a user.

Each of the embodiments described above may be implemented independently, but the structures of each embodiment may be applied in combination to other embodiments.

While the disclosure has been described with reference to embodiments illustrated in the drawings, this is merely illustrative. It is to be understood that various equivalent modifications and variations of the embodiments may be made by a person having an ordinary skill in the art without departing from the spirit and scope of the disclosure. Therefore, the true technical scope of protection of the disclosure should be determined by the technical spirit of the appended claims. Accordingly, the true technical protection scope of the disclosure should be defined by the technical spirit of the appended claims.

The specific implementations described in the embodiments are examples and do not limit the scope of the embodiments in any method. In addition, unless “essential,” “important,” and the like are not specifically mentioned, it may not be a necessary component for the application of the disclosure.

In the specification (especially in the claims) of the embodiments, the use of the term “the” and similar indicating terms may correspond to both singular and plural. In the case where a range is described in the embodiment, since it includes the disclosure in which the individual values belonging to the range are applied, unless otherwise stated, it is the same as describing each individual value constituting the range in the detailed description. Finally, in case that there is no explicit or contradictory description of operations constituting the method according to the embodiment, the operations may be performed in a suitable order. The embodiments are not necessarily limited to the order in which the operations are described. The use of all the examples or exemplary terms in the embodiments is merely for describing the embodiments in detail. Accordingly, the scope of the embodiments may not be limited by the examples or exemplary terms, unless limited by the claims. In addition, those skilled in the art may recognize that various modifications, combinations, and changes may be configured according to design conditions and factors within the scope of the appended claims or equivalents thereof.

A display device according to the embodiments of the disclosure may provide a display device with good quality. The scope of the disclosure is not limited by the effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the FIGS., it will be understood by those of ordinary skill in the art that various changes in form and details may be made therein without departing from the spirit and scope as defined by the following claims.

What is claimed is:

1. A display device comprising:
a substrate which includes a display area including a subpixel and a peripheral area around the display area;
horizontal power voltage lines which are disposed in the display area and extend in a first direction;
vertical power voltage lines which are disposed in the display area, are positioned on a different layer from the horizontal power voltage lines, extend in a second direction intersecting the first direction, and are electrically connected to the horizontal power voltage lines; and
test lines which are disposed in the peripheral area, are positioned in a different layer from the vertical power voltage lines, are positioned to be closer to the substrate than the vertical power voltage lines, extend in the second direction, and are electrically connected to the horizontal power voltage lines.

2. The display device of claim 1, further comprising a semiconductor layer positioned on an insulating layer that covers at least one of the horizontal power voltage lines.

3. The display device of claim 2, wherein the semiconductor layer includes an oxide semiconductor material.

4. The display device of claim 2, wherein the test lines are positioned on an insulating layer that covers the semiconductor layer.

5. The display device of claim 4, wherein the subpixel includes a transistor, and
the test lines and gate electrodes of the transistor are formed as a same layer.

6. The display device of claim 1, wherein the test lines and at least one of the horizontal power voltage lines are positioned on a same layer.

7. The display device of claim 6, wherein the subpixel includes a capacitor, and
the test lines and an electrode of the capacitor are positioned on a same layer.

8. The display device of claim 1, wherein the vertical power voltage lines are positioned on an insulating layer that covers the test lines.

9. The display device of claim 8, wherein the subpixel includes a transistor, and
the test lines and source and drain electrodes of the transistor are positioned on a same layer.

10. The display device of claim 1, wherein the test lines include a plurality of test lines, each of the plurality of test lines is electrically connected to a corresponding horizontal power voltage line among a plurality of horizontal power voltage lines, and
the plurality of test lines are positioned on a same layer.

11. The display device of claim 1, wherein the test lines include a plurality of test lines, each of the plurality of test lines is electrically connected to a corresponding horizontal power voltage line among a plurality of horizontal power voltage lines, and
the plurality of test lines are positioned on different layers.

12. The display device of claim 1, wherein the test lines are electrically connected to the horizontal power voltage lines through connection interconnects.

13. The display device of claim 1, wherein the subpixel includes a transistor,
the horizontal power voltage lines include a horizontal first power line which is electrically connected to the transistor and extends in the first direction,
the vertical power voltage lines include a vertical first power line which traverses the subpixel in the second direction and is electrically connected to the horizontal first power line, and
the test lines include a first power test line electrically connected to the horizontal first power line.

14. The display device of claim 1, wherein the horizontal power voltage lines include a horizontal second power line which traverses the subpixel and extends in the first direction,
the vertical power voltage lines include a vertical second power line which traverses another subpixel of a pixel including the subpixel in the second direction and is electrically connected to the horizontal second power line,
the horizontal second power line and the vertical second power line are electrically connected to a display element, and
the test lines include a second power test line electrically connected to the second horizontal power line.

15. A method of manufacturing a display device, the method comprising:
preparing a substrate which includes a display area including a subpixel and a peripheral area outside the display area;
forming horizontal power voltage lines which are disposed in the display area and extend in a first direction;
forming test lines which are disposed in the peripheral area, extend in a second direction intersecting the first direction, and are electrically connected to the horizontal power voltage lines; and
forming vertical power voltage lines which are disposed in the display area, are positioned on a different layer from the horizontal power voltage lines and the test lines, extend in the second direction, and are electrically connected to the horizontal power voltage lines.

16. The method of claim 15, wherein the test lines and at least one of the horizontal power voltage lines are formed on a same layer.

17. The method of claim 15, further comprising, after the forming of the horizontal power voltage lines, forming a semiconductor layer positioned on an insulating layer that covers at least one of the horizontal power voltage lines, wherein the test lines are positioned on an insulating layer that covers the semiconductor layer.

18. The method of claim 15, wherein the forming of the vertical power voltage lines includes forming an insulating layer that covers the test lines and forming the vertical power voltage lines to be positioned on the insulating layer.

19. An electronic device comprising:
A display device,
wherein the display device includes:
a substrate which includes a display area including a subpixel and a peripheral area outside the display area;
horizontal power voltage lines which are disposed in the display area and extend in a first direction;
vertical power voltage lines which are disposed in the display area, are positioned on a different layer from the horizontal power voltage lines, extend in a second direction intersecting the first direction, and are electrically connected to the horizontal power voltage lines; and
test lines which are disposed in the peripheral area, are positioned in a different layer from the vertical power voltage lines, are positioned to be closer to the substrate than the vertical power voltage lines, extend in the second direction, and are electrically connected to the horizontal power voltage lines.

20. The electronic device of claim 19, wherein the electronic device is at least one of a smart watch, a mobile phone, a smartphone, a portable computer, a tablet personal computer (PC), a watch phone, an automotive display, a smart glass, a portable multimedia player (PMP), a navigation system, an ultra-mobile computer (UMPC), a head mounted display (HMD) device, a virtual reality (VR) device, a mixed reality (MR) device, and an augmented reality (AR) device.
